(19) United States
(12) Patent Application Publication
(10) Pub. No.: US 2024/0169126 A1
(43) Pub. Date: May 23, 2024

(54) SIMULATION FIDELITY FOR END-TO-END VEHICLE BEHAVIOR

(71) Applicant: GM Cruise Holdings LLC, San Francisco, CA (US)

(72) Inventors: Spyridon Zafeiropoulos, Carmel, IN (US); Luke Murchison, Belmont, CA (US); Lynn Marie Sarcione, Austin, TX (US); Michael Hamilton, San Diego, CA (US)

(73) Assignee: GM Cruise Holdings LLC, San Francisco, CA (US)

(21) Appl. No.: 18/057,138

(22) Filed: Nov. 18, 2022

(51) Int. Cl. G06F 30/27; B60W 40/04; B60W 60/00

(52) U.S. Cl. CPC G06F 30/27; B60W 40/04; B60W 60/00; B60W 2554/4046

(57) ABSTRACT

Systems and methods for evaluating a fidelity of a simulation in replicating a real-world driving scene are provided. A computer-implemented system including one or more non-transitory computer-readable media storing instructions, when executed by one or more processing units, cause the one or more processing units to perform operations including receiving first data collected from a reference driving scene, the first data associated with the reference driving scene and a driving behavior of a first vehicle in the reference driving scene; receiving second data collected from a driving simulation that generates a simulated driving scene and operations of a second vehicle in the simulated driving scene, wherein the simulated driving scene is a simulation of the reference driving scene; and determining a fidelity of the driving simulation based on a comparison between the first data and the second data.

### BACKGROUND

### 1. Technical Field

The present disclosure generally relates to autonomous vehicles and, more specifically, to simulation fidelity for an end-to-end (E2E) vehicle driving simulation.

### 2. Introduction

Autonomous vehicles, also known as self-driving cars, driverless vehicles, and robotic vehicles, may be vehicles that use multiple sensors to sense the environment and move without human input. Automation technology in the autonomous vehicles may enable the vehicles to drive on roadways and to accurately and quickly perceive the vehicle's environment, including obstacles, signs, and traffic lights. Autonomous technology may utilize map data that can include geographical information and semantic objects (such as parking spots, lane boundaries, intersections, crosswalks, stop signs, traffic lights) for facilitating the vehicles in making driving decisions. The vehicles can be used to pick up passengers and drive the passengers to selected destinations. The vehicles can also be used to pick up packages and/or other goods and deliver the packages and/or goods to selected destinations.

### BRIEF DESCRIPTION OF THE DRAWINGS

The various advantages and features of the present technology will become apparent by reference to specific implementations illustrated in the appended drawings. A person of ordinary skill in the art will understand that these drawings show only some examples of the present technology and would not limit the scope of the present technology to these examples. Furthermore, the skilled artisan will appreciate the principles of the present technology as described and explained with additional specificity and detail through the use of the accompanying drawings in which:

FIG. 1 illustrates a scheme for evaluating simulation fidelity for an end-to-end (E2E) autonomous vehicle (AV) driving simulation, according to some examples of the present disclosure;

FIG. 2 illustrates a scheme for evaluating simulation fidelity for an E2E AV driving simulation, according to some examples of the present disclosure;

FIG. 3 illustrates a scheme for evaluating simulation fidelity for an E2E AV driving simulation, according to some examples of the present disclosure;

FIG. 4 illustrates a scheme for evaluating simulation fidelity for an E2E AV driving simulation, according to some examples of the present disclosure;

FIG. 5 illustrates a simulation fidelity evaluation process, according to some examples of the present disclosure;

FIG. 6 illustrates a simulation fidelity evaluation process, according to some examples of the present disclosure;

FIG. 7 illustrates a simulation integrity evaluation process, according to some examples of the present disclosure;

FIG. 8 illustrates an example system environment that may be used to facilitate AV dispatch and operations, according to some aspects of the disclosed technology; and

FIG. 9 illustrates an example processor-based system with which some aspects of the subject technology may be implemented.

### DETAILED DESCRIPTION

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a more thorough understanding of the subject technology. However, it will be clear and apparent that the subject technology is not limited to the specific details set forth herein and may be practiced without these details. In some instances, structures and components are shown in block diagram form to avoid obscuring the concepts of the subject technology.

Autonomous vehicles (AVs) can provide many benefits. For instance, AVs may have the potential to transform urban living by offering opportunities for efficient, accessible and affordable transportation. An AV may be equipped with various sensors to sense an environment surrounding the AV and collect information (e.g., sensor data) to assist the AV in making driving decisions. To that end, the collected information or sensor data may be processed and analyzed to determine a perception of the AV's surroundings, extract information related to navigation, and predict future motions of the AV and/or other traveling agents in the AV's vicinity. The predictions may be used to plan a path for the AV (e.g., from a starting position to a destination). As part of planning, the AV may access map information and localize itself based on location information (e.g., from location sensors) and the map information. Subsequently, instructions can be sent to a controller to control the AV (e.g., for steering, accelerating, decelerating, braking, etc.) according to the planned path.

The operations of perception, prediction, planning, and control of an AV may be implemented using a combination of hardware and software components. For instance, an AV stack or AV compute process performing the perception, prediction, planning, and control may be implemented using one or more of software code and/or firmware code. However, in some embodiments, the software code and firmware code may be supplemented with hardware logic structures to implement the AV stack and/or AV compute process. The AV stack or AV compute process (the software and/or firmware code) may be executed on processor(s) (e.g., general purpose processors, central processing units (CPUs), graphical processing units (GPUs), digital signal processors (DSPs), application specific integrated circuits (ASICs), etc.) and/or any other hardware processing components on the AV. Additionally, the AV stack or AV compute process may communicate with various hardware components (e.g., onboard sensors and control systems of the AV) and/or with an AV infrastructure over a network.

Training and testing AVs in the physical world can be challenging. For instance, to provide good testing coverage, an AV may be trained and tested to respond to various driving scenarios (e.g., millions of physical road test scenarios) before it can be deployed in an unattended, real-life roadway system. As such, it may be costly and time-consuming to train and test AVs on physical roads. Further, there may be test cases that are difficult to create or too dangerous to cover in the physical world. Accordingly, it may be desirable to train and validate AVs in a simulation environment.

A simulator may simulate (or mimic) real-world conditions (e.g., roads, lanes, buildings, obstacles, other traffic participants, trees, lighting conditions, weather conditions, etc.) so that the AV stack and/or AV compute process of an AV may be tested in a virtual environment that is close to a real physical world. Testing AVs in a simulator can be more efficient and allow for creation of specific traffic scenarios. To that end, the AV compute process implementing the perception, prediction, planning, and control algorithms can be developed, validated, and fine-tuned in a simulation environment. More specifically, the AV compute process may be executed in an AV simulator (simulating various traffic scenarios), and the AV simulator may compute metrics related to AV driving decisions, AV response time, etc. to determine the performance of an AV to be deployed with the AV compute process.

In some instances, it may be desirable to capture a real-world driving scene and then convert and/or replay the captured scene in a simulation environment (e.g., a virtual driving environment) so that the performance (e.g., driving behaviors) of an AV compute process can be analyzed, assessed, corrected, and/or improved. In an example, an AV may not perform well in a certain real-world driving scene, and thus it may be desirable to analyze (or debug) and/or improve the AV compute process offline in a simulation environment. In other examples, an AV compute process may be updated (e.g., a new AV software version), and thus it may be desirable to evaluate the performance of the updated AV compute process prior to deploying in a real-world vehicle. Accordingly, AV simulation can benefit debug of real-world AV driving performance and various stages of AV code development and release integration. To be able to evaluate the performance of an AV compute process based on a simulation and to obtain the expected result when the AV compute process is deployed in a vehicle for real-world driving, the fidelity of the simulation in replicating a real-world driving scenario is important. Because the behavior of an AV may depend not only on the AV compute process but also its interaction with the surrounding environment, there is a need to have an end-to-end (E2E) simulation with a high fidelity.

Accordingly, the present disclosure provides techniques to measure and/or quantify the fidelity of an E2E AV simulation at various fidelity levels via structured testing. An E2E simulation may refer to a simulation that simulates each component that contributes to a driving decision or a driving behavior of an AV. As an example, an E2E AV simulation may simulate a driving scene, sensors that capture information (e.g., roadways, objects, and/or weather elements) associated with the driving scene, an AV compute process that utilizes the captured sensor data to determine a driving decision, and vehicle dynamics of the AV. In some instances, an E2E AV simulation may also be referred to as an integrated simulation or a driving simulation. As used herein, a fidelity of an E2E simulation may refer to the accuracy of the simulation in replicating a certain reference driving scenario and the overall performance (e.g., behaviors) of an AV driving in the driving reference scenario. Stated differently, the fidelity may refer to the accuracy of the E2E simulation compared to a real-world driving scene and AV driving behaviors being modeled. The fidelity can be a numerical value (e.g., a score) within a certain range. In some examples, the reference driving scenario can be a real-world driving scenario. In other examples, the reference driving scene can be a synthetic driving scene with a high fidelity. As used herein, a fidelity level may refer to the granularity in which a fidelity is measured. For example, besides measuring the fidelity of an E2E simulation, a finer fidelity can be measured at a component simulation level, a subsystem simulation level, etc.

According to an aspect of the present disclosure, a computer-implemented system may implement an AV simulation fidelity test at various fidelity levels. The AV simulation fidelity test can include a continuous feedback loop to allow for gaps in simulation fidelity to be identified and addressed. For example, the computer-implemented system may receive first data (or reference data) collected from a reference driving scene, where the first data may be associated with the reference driving scene and a driving behavior of a first vehicle in the reference driving scene. The computer-implemented system may further receive second data collected from a driving simulation of a simulated driving scene and operations of a second vehicle driving in the simulated driving scene, where the simulated driving scene may be a simulation of the reference driving scene and the second data may be associated with the simulated driving scene and a driving behavior of the second vehicle in the simulated driving scene. The computer-implemented system may further determine a fidelity of the driving simulation based on a comparison between the first data and the second data.

In some aspects, the reference driving scene is a real-world driving scene. In this regard, the first data may be collected from the real-world driving scene. The first data may include sensing information collected from sensors on the first vehicle, a drive log (e.g., including the driving behavior, the pose, and/or the dynamics of the first vehicle), and/or a compute log (e.g., object classification, prediction results, path planning, etc.). The second data may include similar types of information as the first data but collected from the driving simulation. In some instances, each piece of information or data in the first and second data may include a timestamp. In this way, the first and second data can later be time-aligned (or correlated) for comparison. In other aspects, the reference driving scene is another simulated driving scene (e.g., from a high-fidelity E2E simulation) replicating a real-world driving scene.

In some aspects, the determining the fidelity of the driving simulation may include comparing the driving behavior of the first vehicle in the reference driving scene at a first time instant to the driving behavior of the second vehicle in the simulated driving scene at a second time instant corresponding to the first time instant. That is, the determination may include establishing a timing relationship between the first data and the second data (e.g., based on a correlation of timestamps in the driving log and compute log) and performing a per time tick comparison between the reference driving scene and the simulated driving scene. Additionally or alternatively, the determination of the fidelity of the driving simulation can include measuring a fidelity of each of one or more components of the driving simulation individually. Some examples of simulated components (or component models) in an E2E simulation may include, but not limited to, simulations of a sensor, a placement of an object (e.g., buildings, road signs, road artifacts, trees, etc.) in a driving scene, a motion of an object (e.g., another vehicle, pedestrian, a cyclist, etc.) in a driving scene, a vehicle dynamic (e.g., a distribution of vehicle mass, velocity, acceleration, braking, steering, etc.), a vehicle pose (e.g., the location and/or an orientation of the vehicle), a road attribute (e.g., road friction, road inclination, etc.), a classification of an object, a prediction of a traffic participant, and/or any factors that contribute to a driving decision made by a vehicle.

In some further aspects, it may be desirable to execute the simulation fidelity test in a closed loop. That is, the computer-implemented system can feed a fidelity measure (e.g., a global E2E fidelity) back to the simulation fidelity test so that a certain simulation parameter can be adjusted to improve the fidelity of the E2E vehicle simulation. To that end, the computer-implemented system may iteratively calculate a fidelity of the simulation and adjust a parameter associated with the simulation. More specifically, during a current iteration, the computer-implemented system may adjust a parameter associated with the simulation based on a fidelity value calculated for a previous iteration. The adjusted parameter may be associated with a component of the simulation. The component may include, but limited to, a sensor in the simulated driving scene, an object in the simulated driving scene, a vehicle pose, a vehicle dynamic, a road attribute, etc. In one aspect, the computer-implemented system may identify a mismatch between a first component in the reference driving scene and a component model (that models the first component) in the simulation and iteratively adjust a parameter of the component model until a fidelity of the component model is sufficiently close (e.g., based on a certain threshold fidelity) to the actual first component. The iterative adjustments for the component model may be based on structured component testing (e.g., using a predetermined set of test cases). Subsequently, the adjusted (improved) component model may be used in the E2E vehicle simulation for E2E fidelity testing again. In general, the closed loop testing can include a global loop at the E2E system level and one or more local loops at the component level as will be discussed further below.

According to a further aspect of the present disclosure, a computer-implemented system may further determine or predict an integrity of a simulation (e.g., an E2E vehicle simulation) using a simulation integrity validation model with errors (e.g., the component errors) as inputs to the model. In some instances, the simulation integrity validation model may be referred to as a surrogate model. A surrogate model is a mathematically or statistically defined model or function that replicates or approximates the response of a full-scale simulation output for a selected set of inputs. Stated differently, a surrogate model is a model that mimics input-to-output behavior of a complex system. For example, the computer-implemented system may receive first data collected from a real-world driving scene (e.g., a reference driving scene), where the first data may be associated with the real-world driving scene and a driving behavior of a real-world vehicle in the real-world driving scene. The computer-implemented system may execute a simulation that simulates a simulated vehicle driving in a simulated driving scene. The computer-implemented system may collect, from the simulation, second data associated with the simulated driving scene and a driving behavior of the simulated vehicle in the simulated driving scene. The computer-implemented system may determine, based on the first data and the second data, a plurality of measurements, where each of the measurements may correspond to a difference between a component of a plurality of components in the real-world driving scene and a respective one of a plurality of simulated components used by the simulation. The computer-implemented system may process the plurality of measurements using a simulation integrity validation model to generate a simulation integrity score. The simulation integrity validation model can be a statistical model such as a generalized linear model (GLM) or a machine learning (ML) model. The simulation integrity score may be a pass or a failure.

The systems, schemes, and mechanisms described herein can advantageously provide a systematic approach to understand and evaluate the fidelity of an E2E vehicle simulation with respect to a reference driving scene (e.g., a real-world driving scene). Using a closed loop at the E2E system level and at the component level can allow for identification of simulation component(s) in the E2E vehicle simulation that may incorrectly model respective component(s) in the reference driving scene and adjustments for those problematic simulation components. Further, using a statistical or ML model to determine the integrity of a simulation is a pass or fail based on errors in the components of the simulation can eliminate the need for human reviewers to inspecting and qualify the integrity of the simulation. This can save time and cost.

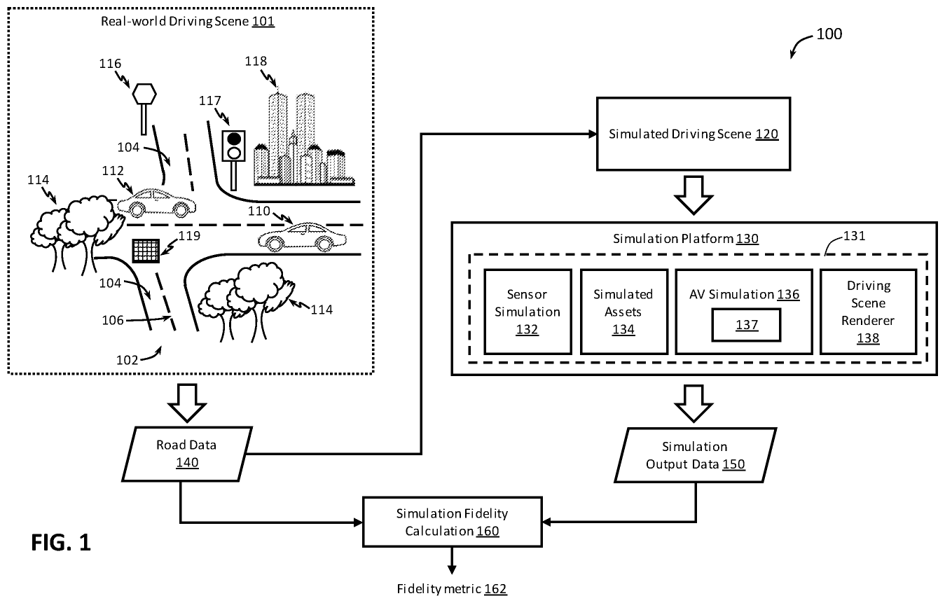

FIG. 1 illustrates a scheme 100 for evaluating simulation fidelity for an end-to-end AV driving simulation, according to some examples of the present disclosure. As shown in FIG. 1, a real-world driving scene 101 may include an AV 110 driving on a roadway system 102. The roadway system 102 may include roads and lanes 104 and road markings 106. Other vehicles such as a vehicle 112 may also be driving on the roadway system 102. As further shown in FIG. 1, the real-world driving scene 101 may include trees 114, a road sign 116, a traffic light 117, buildings 118, and an object 119 (e.g., an obstacle, a road barrier, a traffic cone, etc.) located around the roadway system 102. In general, the real-world driving scene 101 may include various roadside objects (e.g., moving objects and/or stationary objects) at various locations. In some instances, the real-world driving scene 101 may be part of an operational design domain (ODD). An ODD is a specific domain in which an autonomous driving system is designed to operate.

The AV 110 may be a fully autonomous vehicle or a semi-autonomous vehicle. A fully autonomous vehicle may make driving decisions and drive the vehicle without human inputs. A semi-autonomous vehicle may make at least some driving decisions without human inputs. In some examples, the AV 110 may be a vehicle that switches between a semi-autonomous state and a fully autonomous state and thus, the AV 110 may have attributes of both a semi-autonomous vehicle and a fully autonomous vehicle depending on the state of the vehicle.

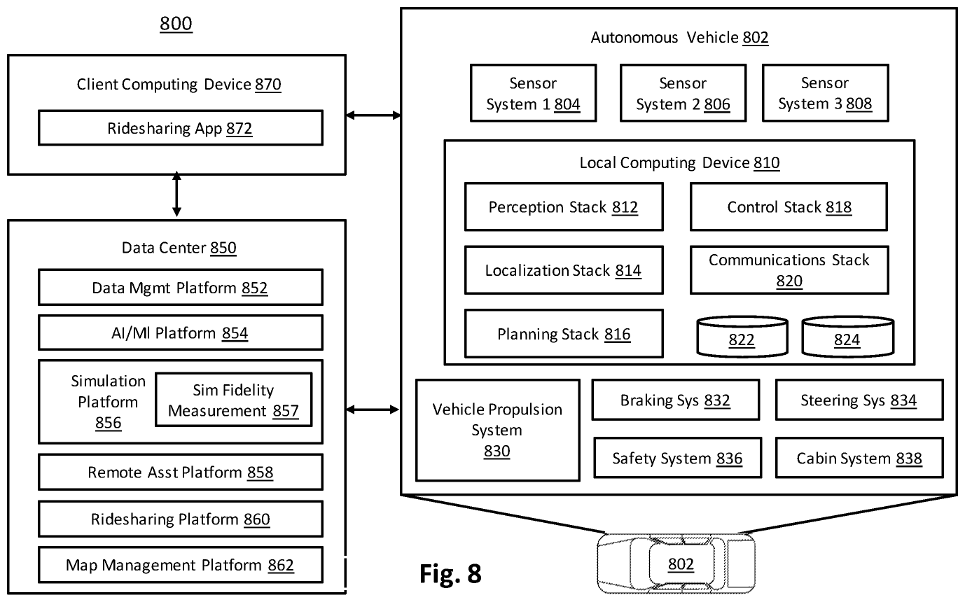

As will be discussed more fully below with reference to FIG. 8, the AV 110 may include various sensors and an onboard computer or local computing device. The sensors may include a wide variety of sensors, which may broadly categorize into a computer vision (“CV”) system, localization sensors, and driving sensors. As an example, the AV 110's sensors may include one or more cameras. The one or more cameras may capture images of the surrounding environment of the AV 110. In some instances, the sensor may include multiple cameras to capture different views, e.g., a front-facing camera, a back-facing camera, and side-facing cameras. In some instances, one or more cameras may be implemented using a high-resolution imager with a fixed mounting and field of view. One or more cameras may have adjustable field of views and/or adjustable zooms. In some embodiments, the cameras may capture images continually or at some intervals during operation of the AV 110. The cameras may transmit the captured images to the onboard computer of the AV 110 for further processing, for example, to assist the AV 110 in determining certain action(s) to be carried out by the AV 110.

Additionally or alternatively, the AV 110's sensors may include one or more light detection and ranging (LIDAR) sensors. The one or more LIDAR sensors may measure distances to objects in the vicinity of the AV 110 using reflected laser light. The one or more LIDAR sensors may include a scanning LIDAR that provides a point cloud of the region scanned. The one or more LIDAR sensors may have a fixed field of view or a dynamically configurable field of view. The one or more LIDAR sensors may produce a point cloud (e.g., a collection of data points in a 3D space) that describes the shape, contour, and/or various characteristics of one or more object in the surrounding of the AV 110 and a distance of the object away from the AV 110. For instance, the point cloud may include data points representing at least some of the trees 114, the road sign 116, the traffic light 117, the buildings 118, and the object 119 located around the roadway system 102. The one or more LIDAR sensors may transmit the captured point cloud to the onboard computer of the AV 110 for further processing, for example, to assist the AV 110 in determining certain action(s) to be carried out by the AV 110.

Additionally or alternatively, the AV 110's sensors may include one or more RADAR sensors. RADAR sensors may operate in substantially the same way as LIDAR sensors, but instead of the light waves used in LIDAR sensors, RADAR sensors use radio waves (e.g., at frequencies of 24, 74, 77, and 79 gigahertz (GHz)). The time taken by the radio waves to return from the objects or obstacles to the AV 110 is used for calculating the distance, angle, and velocity of the obstacle in the surroundings of the AV 110.

Additionally or alternatively, the AV 110's sensors may include one or more location sensors. The one or more location sensors may collect data that is used to determine a current location of the AV 110. The location sensors may include a global positioning system (GPS) sensor and one or more inertial measurement units (IMUs). The one or more location sensors may further include a processing unit (e.g., a component of the onboard computer, or a separate processing unit) that receives signals (e.g., GPS data and IMU data) to determine the current location of the AV 110. The location determined by the one or more location sensors can be used for route and maneuver planning. The location may also be used to determine when to capture images of a certain object. The location sensor may transmit the determined location information to the onboard computer of the AV 110 for further processing, for example, to assist the AV 110 in determining certain action(s) to be carried out by the AV 110.

In general, the AV 110's sensors may include any suitable sensors including but not limited to, photodetectors, one or more cameras, RADAR sensors, sound navigation and ranging (SONAR) sensors, LIDAR sensors, GPS, wheel speed sensors, weather sensors, IMUs, accelerometers, microphones, strain gauges, pressure monitors, barometers, thermometers, altimeters, etc. Further, the sensors may be located in various positions in and around the AV 110.

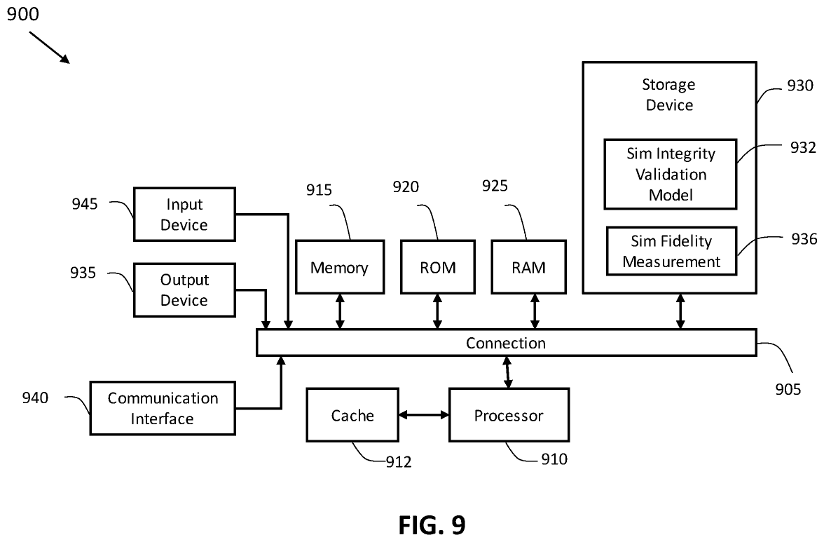

The AV 110's onboard computer may include one or more processors, memory, communication interface, for example, similar to the system 900 of FIG. 9. In an example, the onboard computer may receive data collected from the AV 110's sensors and may store the collected sensor data at a memory of the onboard computer. As an example, the onboard computer may implement an AV compute process. An AV compute process (e.g., an AV software stack) may be executed on the AV 110's onboard computer to determine a driving decision based on the collected sensor data. To that end, the AV compute process may perform the tasks of perception, prediction, planning, and control.

For perception, the AV compute process may perform analyze the collected sensor data (e.g., camera images, point clouds, location information, etc.) and output an understanding or a perception of the environment surrounding the AV 110. In particular, the AV compute process may extract information related to navigation and making driving decisions. For instance, the AV compute process may detect objects such as other cars, pedestrians, trees, bicycles, and objects traveling on or near the roadway systems 102 on which the AV 110 is traveling, and indications surrounding the AV 110 (such as construction signs, traffic cones, traffic lights, stop indicators, and other street signs). In the illustrated example of FIG. 1, the AV compute process may detect one or more of the vehicle 112, the trees 114, the road sign 116, the traffic light 117, the buildings 118, and/or the objects 119 in the surroundings of the AV 110. Further, in some examples, as part of performing the perception, the AV compute process may utilize one or more classifiers (e.g., trained using ML) to identify particular objects. For example, a multi-class classifier may be used to classify each object in the environment of the AV 110 as one of a set of potential objects, e.g., a vehicle, a pedestrian, or a cyclist. As another example, a pedestrian classifier may recognize pedestrians in the environment of the AV 110, a vehicle classifier may recognize vehicles in the environment of the AV 110, etc.

For prediction, the AV compute process may perform predictive analysis on at least some of the recognized objects, e.g., to determine projected pathways of other vehicles, bicycles, and pedestrians. The AV compute process may also predict the AV 110's future trajectories, which may enable the AV 110 to make appropriate navigation decisions. In some examples, the AV compute process may utilize one or more prediction models trained using ML to determine future motions and/or trajectories of other traffic agents and/or of the AV 110 itself.

For AV planning, the AV compute process may plan maneuvers for the AV 110 based on map data, perception data, prediction information, and navigation information, e.g., a route instructed by a fleet management system. In some examples, the AV compute process may also receive map data from a map database (e.g., stored locally at the AV 110 or at a remote server) including data describing roadways such as the roadway system 102 (e.g., locations of roadways, connections between roadways, roadway names, speed limits, traffic flow regulations, toll information, etc.), buildings such as the buildings 118 (e.g., locations of buildings, building geometry, building types), and other objects (e.g., location, geometry, object type). In general, as part of planning, the AV compute process may determine a pathway for the AV 110 to follow. When the AV compute process detects moving objects in the environment of the AV 110, the AV compute process may determine the pathway for the AV 110 based on predicted behaviors of the objects provided by the prediction and right-of-way rules that regulate behavior of vehicles, cyclists, pedestrians, or other objects. The pathway may include locations for the AV 110 to maneuver to, and timing and/or speed of the AV 110 in maneuvering to the locations.

For AV control, the AV compute process may send appropriate commands to instruct movement-related subsystems (e.g., actuators, steering wheel, throttle, brakes, etc.) of the AV 110 to maneuver according to the pathway determined by the planning.

According to aspects of the present disclosure, the AV 110 may collect sensor data from the sensors, log data computed by the AV compute process, behaviors of the AV 110, and/or driving decisions made by the AV 110 as the AV 110 drives in the real-world driving scene 101 to generate road data 140. Stated differently, the road data 140 may include sensor messages (e.g., captures of images from cameras, LIDAR data from LIDAR sensors, RADAR data from RADAR sensors, etc.), a compute log, and/or a drive log. The road data 140 may include various data at various points of time. For instance, each piece of data in the road data 140 may include a timestamp. The road data 140 can be used by a simulation platform (e.g., the simulation platform 130) to simulate a virtual driving environment replicating the real-world driving scene 101. In this way, an AV compute process can be debugged, trained, developed, and/or evaluated in a simulation environment.

As explained above, to be able to evaluate the performance of an AV compute process based on a simulation and to obtain the expected performance when the AV compute process is deployed a vehicle for real-world driving, the fidelity of the simulation in replicating a real-world driving scenario and/or the integrity of the simulation is important. Because the behavior of an AV may depend not only on the AV compute process but also its interaction with the surrounding environment, it may be desirable to have an understanding of the fidelity or integrity of an E2E simulation.

As further shown in FIG. 1, the road data 140 can be used to generate a simulated driving scene 120 for use in a simulation. To that end, a simulation platform 130 may be used to execute an E2E AV simulation 131. The simulation platform 130 may include a combination of hardware components and software components (e.g., that makes up the E2E AV simulation 131). The software components may simulate various aspects of an AV driving in a driving scene. These software components may be executed using the hardware resources provided by the hardware components (e.g., compute resources such as central processing units (CPUs), graphical processing units (GPUs), storage resources such as memory, network resources, cloud resources) of the simulation platform 130. In some instances, the simulation platform 130 may be similar to the simulation platform 856 of FIG. 8 and/or the system 900 of FIG. 9. In the illustrated example of FIG. 1, the E2E AV simulation 131 may include a sensor simulation 132, an AV simulation 136 including an AV compute process 137, and a driving scene renderer 138. The simulation platform 130 may also include memory to store the simulated assets 134 (e.g., trees, buildings, roadside objects, pedestrians, vehicles, cyclists, etc.).

As part of the E2E AV simulation 131, the sensor simulation 132 may simulate various sensors such as cameras, LIDAR sensors, RADAR sensors, etc. The sensor simulation 132 may include models that model the operations of certain sensors. As an example, a simulation model for a particular camera may take one or more objects or a portion of a driving scene as an input and generate an output image. The model may model the colors, the intensities, and/or the dynamic range (e.g., a maximum intensity and a minimum intensity) of the particular camera. As another example, a simulation model for a LIDAR sensor may take one or more objects or a portion of a driving scene as an input and generate LIDAR returns or data points (e.g., a two-dimensional (2D) point cloud or a three-dimensional (3D) point cloud). As a further example, a simulation model for a RADAR sensor may take one or more objects or a portion of a driving scene as an input and generate output RADAR returns or data points.

The AV simulation 136 may simulate functionalities of the real-world AV 110, and the AV compute process 137 may be substantially the same as the AV compute process that is deployed in the real-world AV 110. For instance, the AV compute process 137 may perform perception, prediction, planning, and control as discussed above.

As part of the E2E AV simulation 131, the driving scene renderer 138 may render the simulated driving scene 120. For instance, the driving scene renderer 138 may replay a simulation of the real-world driving scene 101 based on the road data 140. Stated differently, the driving scene renderer 138 may generate a virtual driving environment in which the AV simulation 136 executing the AV compute process 137 may drive. In some aspects, the driving scene renderer 138 may place one or more of the simulated assets 134 as part of the rendering. The simulated assets 134 can be generated in a variety of ways, for example, based on images and/or LIDAR data captured from a real-world driving scene. The AV compute process 137 may perform perception, prediction, planning, and/or control based on sensor data generated by the sensor simulation 132.

Simulation output data 150 may be collected from the E2E AV simulation 131. The simulation output data 150 may include similar types of data as the road data 140. For instance, the simulation output data 150 may include simulated sensor messages or data output by the sensor simulation 132, a compute log, and/or a drive log of the simulated AV (executing the AV compute process) driving in the simulated driving scene 120). Similar to the road data 140, the simulation output data 150 may include various data at various points of time in the simulation run, and each piece of data in the simulation output data 150 may be timestamped.

The simulation fidelity calculation block 160 may calculate a fidelity metric 162 for the E2E AV simulation 131 based on a comparison of the simulation output data 150 to the road data 140. The fidelity metric 162 may be a numerical value within a certain range. While FIG. 1 illustrates the simulation fidelity calculation block 160 as a separate block outside of the simulation platform 130, the simulation fidelity calculation block 160 can be implemented as a software component within the simulation platform 130. In general, the simulation fidelity calculation block 160 can be implemented by any suitable computer-implemented system (e.g., the system 900 of FIG. 9). Mechanisms for calculating the fidelity metric 162 and using the fidelity metric 162 as feedback to improve simulation fidelity will be discussed more fully below.

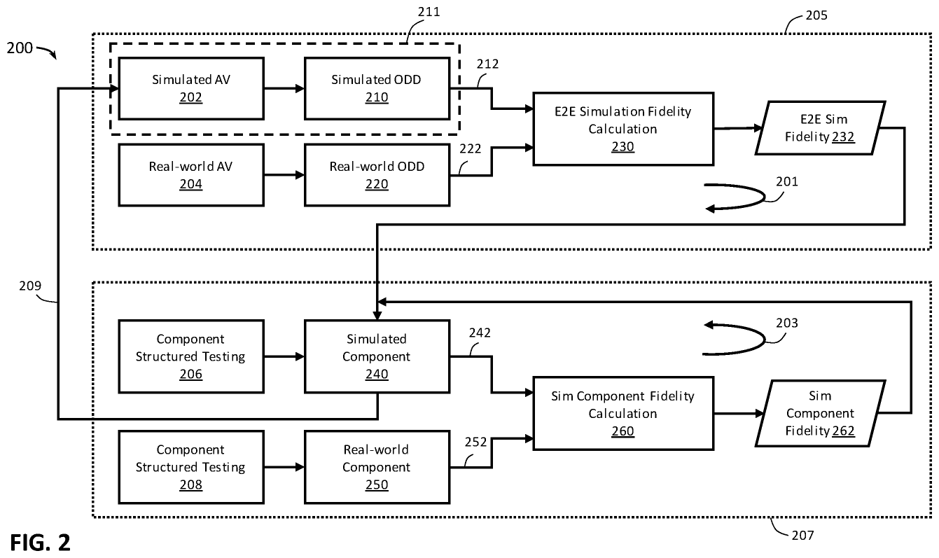

FIG. 2 illustrates a scheme 200 for evaluating simulation fidelity for an E2E AV driving simulation, according to some examples of the present disclosure. The scheme 200 may be implemented by a computer-implemented system (e.g., the system 900 of FIG. 9), the simulation platform 130, and/or the simulation fidelity measurement block 857 of FIG. 8. The scheme 200 may be substantially similar to the scheme 100 but provides a more detailed view in which continuous feedbacks are included to allow for gaps in simulation fidelity to be identified and addressed. As shown in FIG. 2, the scheme 200 may include an E2E fidelity measurement portion 205 and a component fidelity measurement portion 207.

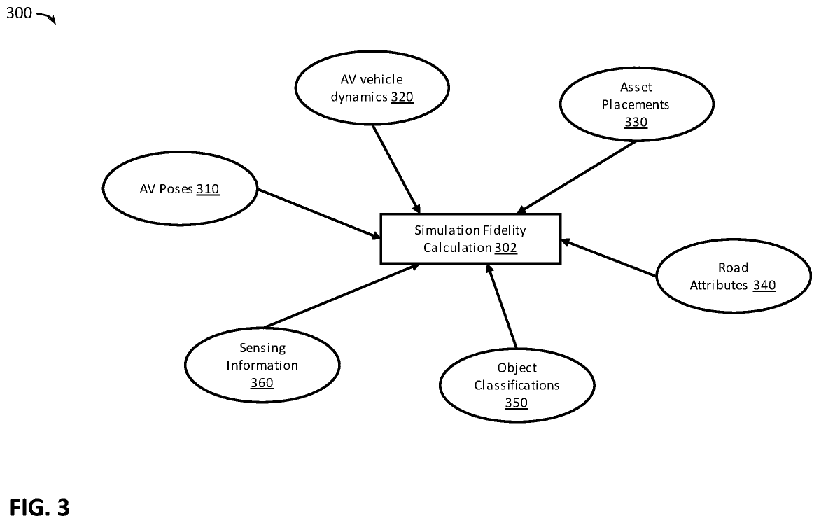

In an aspect, the E2E fidelity measurement portion 205 may include a real-world AV 204 driving in a real-world ODD 220 and a simulated AV 202 driving in a simulated ODD 210. In some aspects, the real-world AV 204 may correspond to the AV 110, the real-world ODD 220 may correspond to the real-world driving scene 101, the E2E AV simulation 211 may correspond to the E2E AV simulation 131, the simulated AV 202 may correspond to the AV simulation 136 (being executed as part of the E2E AV simulation 131), and the simulated ODD 210 may correspond to the simulated driving scene 120 being rendered by the driving scene renderer 138. Road data 222 can be collected from the real-world AV 204 driving in the real-world ODD 220, and simulation output data 212 can be collected from the simulated AV 202 driving in the simulated ODD 210. The road data 222 and the simulation output data 212 can be similar to the road data 140 and the simulation output data 150, respectively. As will be discussed more fully below with reference to FIG. 3, each of the road data 222 and the simulation output data 212 can include information associated with, but not limited to, sensors, placements of objects, object classification, AV pose, AV vehicle dynamics, road attributes, etc. The E2E fidelity measurement portion 205 may include an E2E simulation fidelity calculation block 230 to calculate an E2E simulation fidelity 232 for the E2E AV simulation 211 based on a comparison of the simulation output data 212 to the road data 222. For instance, the E2E simulation fidelity calculation block 230 may compute various differences between the road data 222 and the simulation output data 212. In some aspects, the E2E simulation fidelity calculation block 230 may be implemented as part of the simulation fidelity calculation block 160 of FIG. 1.

In an aspect, the E2E simulation fidelity calculation block 230 may compare a driving behavior (e.g., driving decision, driving performance, reliability, response time, etc.) of the simulated AV 202 in the simulated ODD 210 to a driving behavior (or driving decision, driving performance, reliability, response time, etc.) of the real-world AV 204 in the real-world ODD 204. Some examples of driving behaviors may include, but are not limited to making a right-turn, making a left-turn, going straight, braking, making a stop, and/or various driving decisions associated with certain ODD driving rules. The comparison may also be based on driving performances, reliabilities, response times of the real-word AV 204 in the real-world ODD 220 and the simulated AV 202 in the simulated ODD 210. In general, E2E AV simulation 211 may simulate the simulated AV 202 driving in the simulated ODD 210 for a duration of time (e.g., across a sequence of time instants), and the comparisons may be performed across the sequence of time instants (e.g., a per time tick comparison). For instance, each piece of data in the road data 222 and the simulation output data 212 may include timestamp. In this way, a timing relationship can be established between the road data 222 and the simulation output data 212 on the respective timestamps. That is, the E2E simulation fidelity calculation block 230 may first time-align the road data 222 and the simulation output data 212 before any fidelity related comparisons are made.

As an example, the road data 222 may include information about the real-world AV 204 making a right-turn at an intersection X in the real-world ODD 220 at a time Ta, and the simulation output data 212 may include information about the simulated AV 202 making a right-turn at an intersection Y in the simulated ODD 220 at a time Tb, where the intersection Y (in the simulated ODD 220) corresponds to the intersection X (in the real-world ODD 220). Thus, the E2E simulation fidelity calculation block 230 may time-align the simulation output data 212 to the road data 222 based on time Ta of the road data 222 and the time Tb of the simulation output data 212. In other words, the E2E simulation fidelity calculation block 230 may time-shift the simulation output data 212 such that the simulation output data 212 for time Tb is aligned to the road data 222 for time Ta (e.g., applying a time offset of (Ta-Tb) to the simulation output data 212).

As further shown in FIG. 2, the E2E fidelity measurement portion 205 may include a feedback loop 201 that feeds the E2E simulation fidelity 232 to the component fidelity measurement portion 207. As discussed above, the feedback can allow for gaps in simulation fidelity to be identified and addressed.

For simplicity, FIG. 2 illustrates fidelity testing for one simulated component in the component fidelity measurement portion 207. However, the component fidelity measurement portion 207 can include fidelity testing for any suitable number of simulated components, where the fidelity testing can be individually performed for each component or a group of components (e.g., for subsystem fidelity test). As shown, the component fidelity measurement portion 207 may include performing component structured testing 208 for a real-world component 250 and performing component structured testing 206 for a simulated component 240. The real-world component 250 may be part of the real-world AV 204 and/or the real-world ODD 220. Similarly, the simulated component 240 may be part of the simulated AV 202 and/or the simulated ODD 210. The component structured testing 208 (for the real-world component 250) and the component structured testing 206 (for the simulated component 240) may be defined based on the same test case description (e.g., a set of predetermined test cases). As an example, the real-world component 250 may be a real-world LIDAR sensor, and the simulated component 240 may be a sensor model modeling functionalities and/or properties of the real-world LIDAR sensor. Thus, the component structured testing 208 may test a total number of LIDAR data points returned by the real-world LIDAR sensor for a real-world pedestrian and/or intensities of those LIDAR data points, for example. In a similar way, the component structured testing 206 may test a total number of LIDAR data points output by the simulated LIDAR sensor model, intensities of those LIDAR data points, and/or a spatial distribution of those data points for an input with a simulated pedestrian having attributes of the real-world pedestrian. Various other structured component testing examples will be discussed more fully below with reference to FIG. 3. The component structured testing 208 of the real-world component 250 may generate real-world component data 252, and the component structured testing 206 of the simulated component 240 may generate simulation component data 242.

The component fidelity measurement portion 207 may further include a simulation component fidelity calculation block 260 to calculate a simulation component fidelity 262 based on a comparison of the simulation component data 242 to the real-world component data 252. For instance, the simulation component fidelity calculation block 260 may compute various differences between the real-world component data 252 and the simulation component data 242. Referring to the same example where the components 240 and 250 are LIDAR sensors, the comparison may include calculating a difference in the total number of LIDAR data points between the simulation component data 242 and the real-world component data 252. Additionally or alternatively, the comparison may include calculating a difference in the LDAR data point intensities (e.g., a mean or a variance) between the simulation component data 242 and the real-world component data 252. Additionally or alternatively, the comparison may include calculating a difference in spatial distributions of the LDAR data point intensities between the simulation component data 242 and the real-world component data 252.

In one aspect, the simulation for the simulated component 240 can be updated based on the simulation component fidelity 262 to improve the fidelity of the simulation component 240. For instance, a parameter associated with the simulated component 240 can be adjusted according to the simulation component fidelity 262. The updated simulated component 240 can be used to update the simulated AV 202 driving in the simulated ODD 210 as shown by the arrow 209 that completes the loop 201, and the E2E fidelity measurement portion 205 can be rerun to calculate a new E2E simulation fidelity 232 as discussed above. That is, a parameter of a simulated component 240 can be iteratively adjusted based on a E2E simulation fidelity 232 calculated in a previous iteration. The operations in the loop 201 can be iterated until a calculated E2E simulation fidelity 232 satisfies a threshold. Stated differently, the operations in the loop 201 can be iterated until a calculated E2E simulation fidelity 232 is sufficiently high (indicating that the simulated AV 202 driving in the simulated ODD 210 can closely replicate the real-world AV 204 driving in the real-world ODD 220.

In another aspect, the component fidelity measurement portion 207 may include a feedback loop 203 that feeds the simulation component fidelity 262 to the simulated component 240. In this regard, the component structured testing 206 can be rerun for the updated simulated component 240 to generate update simulation component data 242, and the simulation component fidelity calculation block 260 may determine a new simulation component fidelity 262. That is, a parameter of a simulated component 240 can be iteratively adjusted based on a simulation component fidelity 262 calculated in a previous iteration (within the loop 203). The operations in the loop 203 can be iterated until a calculated simulation component fidelity 262 satisfies a threshold. Stated differently, the operations in the loop 203 can be iterated until a calculated simulation component fidelity 262 is sufficiently high (indicating that the simulated component 240 can closely replicate the real-world component 250.

In general, the feedbacks for the loop 201 and/or the loop 203 can be optional. Additionally, the loop 201 and/or the loop 203 can be performed in any suitable order. For instance, the loop 201 may be performed once, followed by one or more iterations of the loop 203 before the loop 201 is iterated. Further, when the component fidelity measurement portion 207 includes individual component fidelity test for multiple components, the loop 201 may be performed once, followed by at least one iteration of the loop 203 for each component to adjust each component separately before the loop 201 is iterated. In some instances, the loop 203 for each component can be iterated in any suitable order, for example, testing one component after another component (e.g., testing component A and then component B), or interleaving the component test for the components (e.g., testing component A, component B, component A, component B).

FIG. 3 illustrates a scheme 300 for evaluating simulation fidelity for an E2E AV driving simulation, according to some examples of the present disclosure. The scheme 300 may be implemented by a computer-implemented system (e.g., the system 900 of FIG. 9), the simulation platform 130, and/or the simulation fidelity measurement block 857 of FIG. 8. The scheme 300 may be implemented as part of the operations at the simulation fidelity calculation block 160 of FIG. 1 and/or the simulation component fidelity calculation block 260 of FIG. 2. The scheme 300 is discussed in relation to FIGS. 1 and 2.

As shown in FIG. 3, the scheme 300 may include a simulation fidelity calculation block 302. In some examples, the simulation fidelity calculation block 302 may correspond to the simulation fidelity calculation block 160 of FIG. 1. In some examples, the simulation fidelity calculation block 302 may correspond to the simulation component fidelity calculation block 260. In an aspect, the simulation fidelity calculation block 302 may receive first data associated with a first vehicle driving in a real-world driving scene and second data associated with a second vehicle driving in a simulated driving scene. In one example, the first data, the first vehicle, and the real-world driving scene may correspond to the road data 140, the AV 110, the real-world driving scene 101 of FIG. 1, respectively. The second data, the second vehicle, and simulated driving scene may correspond to the simulation output data 212, the AV simulated by the AV simulation 136, and the simulated driving scene 120 of FIG. 1, respectively. In another example, the first data, first vehicle, and the real-world driving scene may correspond to the road data 222, the real-world AV 204, and the real-world ODD 220 of FIG. 2, respectively. The second data, the second vehicle, and simulated driving scene may correspond to the simulation output data 212, the simulated AV 202, and the simulated ODD 210 of FIG. 2, respectively. In general, the simulation fidelity calculation block 302 may calculate a fidelity for each of a plurality of components of the simulation. In the illustrated example of FIG. 3, the components may include AV poses 310, AV vehicle dynamics 320, asset placements 330, road attributes 340, object classifications 350, and sensing information 360.

In an aspect, the simulation fidelity calculation block 302 may determine a simulation fidelity based on AV poses 310. The AV poses 310 may include an AV location and/or an AV orientation with respect to a respective driving scene (e.g., a certain road, a certain lane, a certain parking spot, a certain landmark, etc.). As an example, the first data may include an indication of a pose of the first vehicle with respect to the real-world driving scene, and the second data may include an indication of a pose of the second vehicle with respect to the simulated driving scene. Thus, the simulation fidelity calculation block 302 may determine the fidelity (e.g., a fidelity score or value) of the simulation by comparing the pose of the first vehicle with respect to the real-world driving scene to the pose of the second vehicle with respect to the environment of the simulated driving scene.

Additionally or alternatively, the simulation fidelity calculation block 302 may determine a simulation fidelity based on AV vehicle dynamics 320. The AV vehicle dynamics 320 may include one or more of a distribution of vehicle mass, a velocity, an acceleration, a steering, a braking, etc. As an example, the first data may include an indication of a vehicle dynamic of the first vehicle in the real-world driving scene, and the second data may include an indication of a vehicle dynamic of the second vehicle in the simulated driving scene. Thus, the simulation fidelity calculation block 302 may determine the simulation fidelity (e.g., a fidelity score or value) by comparing the vehicle dynamic of the first vehicle to the vehicle dynamic of the second vehicle.

Additionally or alternatively, the simulation fidelity calculation block 302 may determine a simulation fidelity based on asset placements 330. The asset placements 330 may include the placement of one or more objects (e.g., stationary or dynamic) in a respective driving scene. Some examples of a stationary object may include buildings, trees, road signs, traffic cones, roadside obstacles, parked cars, etc. Some examples of a dynamic object may include other vehicles, pedestrians, cyclists, etc. As an example, the first data may include an indication of a placement of a first object in the real-world driving scene, and the second data includes an indication of a placement of a second object in the simulated driving scene, where the second object may correspond to the first object. Thus, the simulation fidelity calculation block 302 may determine the simulation fidelity (e.g., a fidelity score or value) by comparing the placement of the first object in the real-world driving scene to the placement of the second object in the simulated driving scene.

Additionally or alternatively, the simulation fidelity calculation block 302 may determine a simulation fidelity based on road attributes 340. The road attributes 340 can include one or more of a lane, a road curvature, a road dimension, a road friction, a road inclination, a pothole, etc. As an example, the first data may include an indication of an attribute of a first road in the real-world driving scene, and the second data may include an indication of an attribute of a second road in the simulated driving scene, where the second road may be generated by a road model modelling the first road. Thus, the simulation fidelity calculation block 302 may determine the simulation fidelity (e.g., a fidelity score or value) by comparing the attribute of the first road in the real-world driving scene to the attribute of the second road in the simulated driving scene.

Additionally or alternatively, the simulation fidelity calculation block 302 may determine a simulation fidelity based on object classifications 350. As discussed above, as part of determining a driving decision, an AV compute process may perform perception and/or prediction to identify objects in a driving scene and classify the object (e.g., whether the identified object is a car, a truck, a sedan, a person, a tree, a building, etc.). As an example, the first data may include a classification of a first object in the real-world driving scene determined by the first vehicle, and the second data may include a classification of a second object in the simulated driving scene determined by the second vehicle, where the second object may correspond to the first object. Thus, the simulation fidelity calculation block 302 may determine the simulation fidelity (e.g., a fidelity score or value) based on by comparing the classification of the first object to the classification of the second object.

Additionally or alternatively, the simulation fidelity calculation block 302 may determine a simulation fidelity based on sensing information 360. The sensing information 360 may be related to cameras, LIDAR sensors, RADAR sensors, etc. For instance, the first data may include first sensor data collected from the real-world driving scene, and the second data may include second sensor data collected from the simulated driving scene. Thus, the simulation fidelity calculation block 302 may determine the simulation fidelity (e.g., a fidelity score or value) by comparing the first sensor data to the second sensor data. In some aspects, the first sensor data may be collected from a sensor in the reference driving scene, the second sensor data is collected from a simulated sensor in the simulated driving scene, and the sensor at the first vehicle and the simulated sensor are of the same senor modality (e.g., camera, LIDAR, or RADAR).

As an example, the first sensor data and the second sensor data may be LIDAR return data. The comparing the first sensor data to the second sensor data may include determining at least one of a difference in a total number of LIDAR points, intensities, or spatial distributions between the first sensor data and the second sensor data. As another example, the first sensor data and the second sensor data may be camera image, and the comparing the first sensor data to the second sensor data may include determining at least one of a difference in colors, intensities, or dynamic ranges (e.g., a range between a maximum intensity and a minimum intensity among the pixels of an image) between the first sensor data and the second sensor data. As a further example, the first sensor data and the second sensor data may be RADAR return data, and the comparing the first sensor data to the second sensor data may include determining a difference in a total number of RADAR data points between the first sensor data and the second sensor data.

In general, for each of the component discussed above, the simulation fidelity calculation block 302 may compute a component difference (e.g., a component error) between a corresponding component data in the first data and a corresponding component data in the second data. In some examples, when a component has several attributes (e.g., colors, intensities, and dynamic ranges for a camera sensor), the simulation fidelity calculation block 302 may calculate a difference or error for each attribute or an aggregated difference based on a sum of a weighted difference for each attribute, for example. For each of the components discussed above, the simulation fidelity may be a numerical value, and having a high value may indicate that a component model may model features and/or functionalities of a respective real-world component well or accurately. In an example, the fidelity value may be one of three values, 1, 2, or 3, and the simulation fidelity calculation block 302 may map the error (or aggregated error) from the comparison for a certain component to one of the three fidelity values. In general, the fidelity value may be in a range of any suitable number of values (e.g., 2, 3, 4, 5, or more).

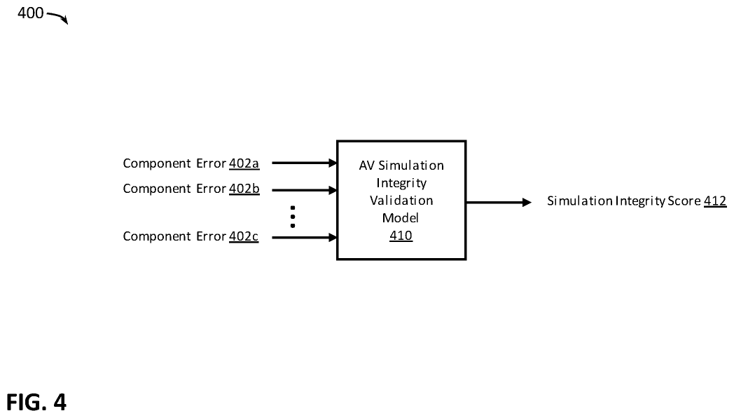

In some aspects, the component fidelity measurement portion 207 in the scheme 200 of FIG. 2 may measure the fidelity of one or more of the components (e.g., the AV poses 310, the AV vehicle dynamics 320, the asset placements 330, the road attributes 340, the object classification 350, and/or the sensing information 360) shown in FIG. 3. As discussed above, the scheme 200 may tune or tweak the fidelity of any one of the components as shown in operations of the loop 203. In some aspects, the errors or differences computed for the fidelities of the components can be assessed together to determine an integrity of the simulation shown in FIG. 4.

FIG. 4 illustrates a scheme 400 for evaluating an integrity of an E2E AV driving simulation, according to some examples of the present disclosure. The scheme 400 may be implemented by a computer-implemented system (e.g., the system 900 of FIG. 9), the simulation platform 130, and/or the simulation fidelity measurement block 857 of FIG. 8. The scheme 400 may be implemented as part of the operations at the simulation fidelity calculation block 160 and/or the E2E simulation fidelity calculation block 230 of FIG. 2. The scheme 400 is discussed in relation to FIGS. 1-3. For instance, the scheme 400 may be used to determine an integrity of the E2E AV simulation 131 of FIG. 1 or the E2E AV simulation of 211 of FIG. 2

As shown in FIG. 4, the scheme 400 may include an AV simulation integrity validation model 410. The AV simulation integrity validation model 410 may take a plurality of component errors 402 (shown as 402a, 402b, . . . , 402c) as inputs and generate a simulation integrity score 412 (e.g., a prediction) based on the component errors 402. Each of the component errors may correspond to a difference between real-world data (e.g., the road data 140 of FIG. 1 or the road data 222 of FIG. 2) and corresponding simulation data (e.g., the simulation output data 150 of FIG. 1 and the simulation output data 212 of FIG. 2). As an example, each component error 402 may correspond to a difference computed for one of the components (e.g., the AV poses 310, the AV vehicle dynamics 320, the asset placements 330, the road attributes 340, the object classifications 350, and the sensing information 360) discussed above with reference to FIG. 3. The simulation integrity score 412 can be a pass or a failure indicated by a value of 1 or 0, respectively, or vice versa.

In some aspects, the AV simulation integrity validation model 410 is a statistical model that models statistical properties of component errors in an E2E AV simulation and makes a prediction for the integrity of the simulation based on the input component errors 402. In some instances, the simulation integrity validation model 410 may be referred to as surrogate model. A surrogate model is a mathematically or statistically defined model or function that replicates or approximates the response of a full-scale simulation output for a selected set of inputs. In some aspects, the AV simulation integrity validation model 410 may be a GLM. A GLM is a flexible generalization of ordinary linear regression. The GLM generalizes linear regression by allowing the linear model to be related to the response variable (e.g., the simulation integrity score 412) via a link function and by allowing the magnitude of the variance of each measurement to be a function of its predicted value. In other aspects, the AV simulation integrity validation model 410 may be an ML model trained to predict an integrity of a simulation based on input component errors 402. For instance, the AV simulation integrity validation model 410 may be a neural network including a plurality of layers, for example, an input layer, followed by one or more hidden layers (e.g., fully-connected layers, convolutional layers, and/or pooling layers) and an output layer. Each layer may include a set of weights and/or biases that can transform inputs received from a previous layer and the resulting outputs can be passed to the next layer. The weights and/or biases in each layer can be trained and adapted, for example, to perform a prediction related to a simulation integrity.

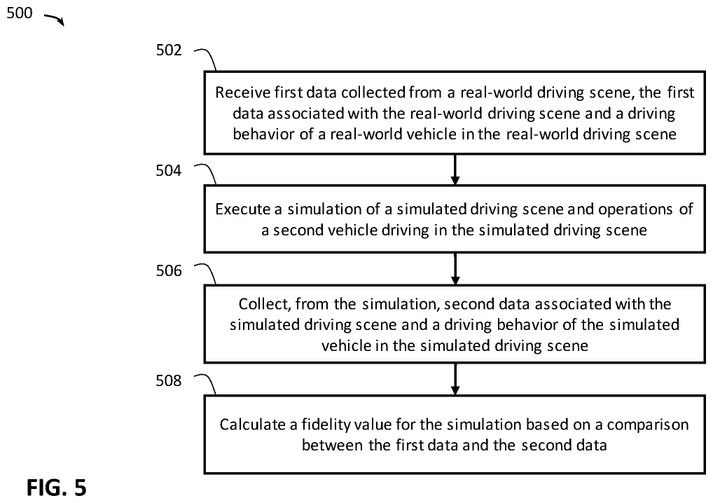

FIG. 5 illustrates a simulation fidelity evaluation process 500, according to some examples of the present disclosure. The process 500 can be implemented by a computer-implemented system such as the simulation platform 130 of FIG. 1, the simulation fidelity measurement block 857 of FIG. 8, and/or the system 900 of FIG. 9. In general, the process 500 may be performed using any suitable hardware components and/or software components. The process 500 may utilize similar mechanisms discussed above with reference to FIGS. 1-3. Operations are illustrated once each and in a particular order in FIG. 5, but the operations may be performed in parallel, reordered, and/or repeated as desired.

At 502, the computer-implemented system may receive first data collected from a real-world driving scene. The first data may be associated with the real-world driving scene and a driving behavior of a real-world vehicle in the real-world driving scene. In one example, the first data, the real-world vehicle, and the real-world driving scene may correspond to the road data 140, the AV 110, and the real-world driving scene 101 of FIG. 1, respectively. In another example, the first data, the first vehicle, and real-world driving scene may correspond to the road data 222, the real-world AV 204, and the real-world ODD 220 of FIG. 2, respectively.

At 504, the computer-implemented system may execute a simulation of a simulated driving scene and operations of a simulated vehicle driving in the simulated driving scene. The simulation may be an E2E simulation similar to the E2E AV simulation 131 of FIG. 1 and/or the E2E AV simulation 211 of FIG. 2. In one example, the simulated vehicle and the simulated driving scene may correspond to a simulated AV simulated by the AV simulation 136 and the simulated driving scene 120 of FIG. 1, respectively. In another example, the simulated vehicle and the simulated driving scene may correspond to the simulated AV 202 and the simulated ODD 210 of FIG. 2, respectively.

At 506, the computer-implemented system may collect, from the simulation, second data associated with the simulated driving scene and a driving behavior of the simulated vehicle in the simulated driving scene. In one example, the second data may correspond to the simulation output data 150 of FIG. 1. In another example, the second data may correspond to the simulation output data 212 of FIG. 2.

At 508, the computer-implemented system may calculate a fidelity value (e.g., the fidelity metric 162 and/or the E2E simulation fidelity 232) for the simulation based on a comparison between the first data and the second data.

In some aspects, as part of calculating the fidelity value, the computer-implemented system may compare the driving behavior of the first vehicle in the reference driving scene and the driving behavior of the second vehicle in the simulated driving scene at each time instant of a sequence of time instants. In some aspects, as part of calculating the fidelity value, the computer-implemented system may calculate a fidelity value for each simulated component of a plurality of simulated components as discussed above with reference to FIGS. 2 and 3.

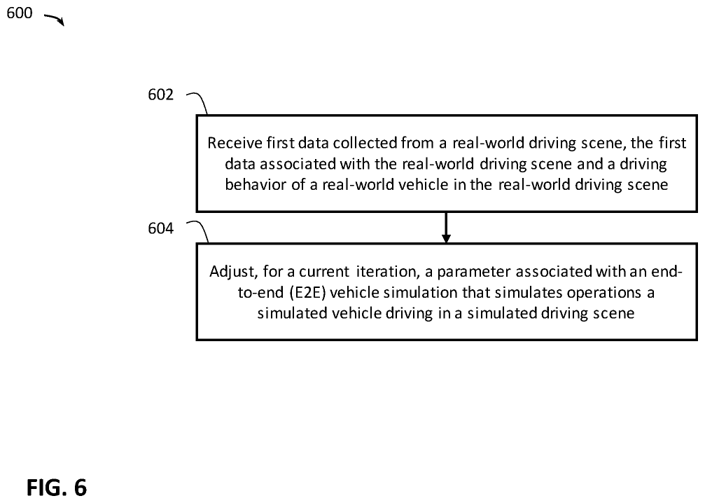

FIG. 6 illustrates a simulation fidelity evaluation process 600, according to some examples of the present disclosure. The process 600 can be implemented by a computer-implemented system such as the simulation platform 130 of FIG. 1, the simulation fidelity measurement block 857 of FIG. 8, and/or the system 900 of FIG. 9. In general, the process 600 may be performed using any suitable hardware components and/or software components. The process 600 may utilize similar mechanisms discussed above with reference to FIGS. 1-5. In some aspects, the process 600 may be implemented in conjunction with the process 500. Operations are illustrated once each and in a particular order in FIG. 6, but the operations may be performed in parallel, reordered, and/or repeated as desired.

At 602, the computer-implemented system may receive first data collected from a real-world driving scene, the first data associated with the real-world driving scene and a performance of a real-world vehicle in the real-world driving scene. In one example, the first data and real-world driving scene may correspond to the road data 140 and the reference driving scene 101 of FIG. 1, respectively. In another example, the first data and real-world driving scene may correspond to the road data 222 and the real-world ODD 220 of FIG. 2, respectively.

At 604, the computer-implemented system may adjust, for a current iteration, a parameter associated with an E2E vehicle simulation (e.g., the E2E AV simulations 131 and/or 211) that simulates operations of a simulated vehicle driving in a simulated driving scene. The adjustment may be based on a fidelity value (e.g., fidelity metric 232) of the E2E vehicle simulation in a previous iteration (e.g., in the loop 201 or 203). The fidelity value may be based on a comparison between second data (e.g., simulation output data 150 and/or 212) collected from the E2E simulation in the previous iteration and the first data (e.g., road data 140 and/or 222).

In some aspects, as part of adjusting the parameter associated with the E2E vehicle simulation 604, the computer-implemented system may execute the E2E vehicle simulation, collect, from the E2E vehicle simulation, the second data associated with the simulated driving scene and a performance of the simulated vehicle in the simulated driving scene, and calculate the fidelity value for the E2E vehicle simulation based on a comparison between the first data and the second data.

In some aspects, the parameter adjusted based on the fidelity value of the E2E vehicle simulation in a previous iteration may be associated with a component model modeling a component in the real-world driving scene. In some aspects, the component may be associated with at least one of a sensor in the real-world driving scene, an object in the real-world driving scene, a pose of the real-world vehicle, a vehicle dynamic of the real-world vehicle, or a road attribute, for example, as discussed above with reference to FIG. 3.

In some aspects, as part of adjusting the parameter associated with the E2E vehicle simulation at 604, the computer-implemented system may identify a mismatch between the component in the real-world driving scene and the component model in the simulated driving scene.

In some aspects, as part of adjusting the parameter associated with the E2E vehicle simulation at 604, the computer-implemented system may execute, based on a component test definition, a test for the component model, collect third data (e.g., the data 242) from the executing the test, receive fourth data (e.g., the data 252) collected from the component in the real-world driving scene, the fourth data based on the component test definition, and calculate a fidelity value for the component model based on a comparison of the third data to the fourth data.

In some aspects, the adjusting the parameter associated with the E2E vehicle simulation at 604 may be based on the fidelity value in the previous iteration failing to satisfy a threshold.

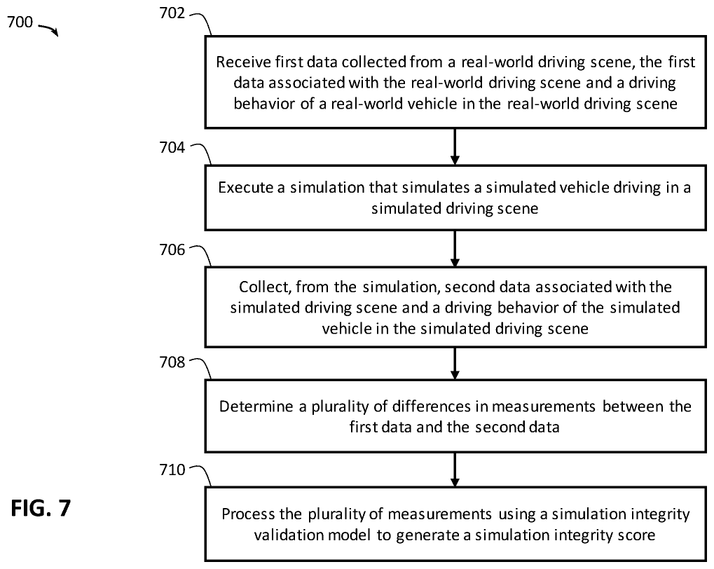

FIG. 7 illustrates a simulation fidelity evaluation process 700, according to some examples of the present disclosure. The process 700 can be implemented by a computer-implemented system such as the simulation platform 130 of FIG. 1, the simulation fidelity measurement block 857 of FIG. 8, and/or the system 900 of FIG. 9. In general, the process 700 may be performed using any suitable hardware components and/or software components. The process 700 may utilize similar mechanisms discussed above with reference to FIGS. 1-64. Operations are illustrated once each and in a particular order in FIG. 7, but the operations may be performed in parallel, reordered, and/or repeated as desired.

Generally speaking, the method 700 includes features similar to method 500 in many respects. For example, operations at 702, 704, and 706 are similar to operations at 502, 504, and 506, respectively; for brevity, a discussion of these elements is not repeated, and these operations may be as discussed above.

At 708, the computer-implemented system may determine a plurality of differences in measurements based on the first data and the second data. Each difference may correspond to a difference in measurements between one component of a plurality of components in the real-world driving scene and a respective one of a plurality of simulated components used by the simulation (e.g., the E2E AV simulations 131 and 211). The differences may correspond to the component errors 402 as discussed above with reference to FIG. 4.

At 710, the computer-implemented system may process the plurality of differences using a simulation integrity validation model (e.g., the model 410 of FIG. 4) to generate a simulation integrity score (e.g., the score 412). In some aspects, the simulation integrity validation model may be a statistical model. In some aspects, the simulation integrity validation model may be a GLM. In some aspects, the simulation integrity validation model may be an ML model. In some aspects, the simulation integrity score may be one (e.g., pass) or zero (failure).

In some aspects, the plurality of differences determined at 708 may be associated with AV poses (e.g., the AV poses 310), AV dynamics (e.g., the AV dynamics 320), road attributes (e.g., the road attributes 340), placements of objects (e.g., the asset placements 330), object classifications (e.g., the object classifications 350), sensor data (e.g., the sensing information 360) as discussed above with reference to FIG. 3. For instances, a first difference of the plurality of differences may correspond to a difference between a pose of the real-world vehicle in the real-world driving scene and a pose of the simulated vehicle in the simulated driving scene. Additionally or alternatively, a second difference of the plurality of differences may correspond to a difference in measurements between a vehicle dynamic of the real-world vehicle in the real-world driving scene and a vehicle dynamic of the simulated vehicle in the simulated driving scene. Additionally or alternatively, a third difference of the plurality of differences may correspond to a difference in measurements between a road attribute in the real-world driving scene and a road attribute in the simulated driving scene. Additionally or alternatively, a fourth difference of the plurality of differences may correspond to a difference in measurements between a placement of a first asset in the real-world driving scene and a placement of a second asset in the simulated driving scene, the second asset corresponding to the first asset. Additionally or alternatively, a fifth difference of the plurality of differences may correspond to a difference in measurements between a classification of a first object in the real-world driving scene and a classification of a second object in the simulated driving scene, the second object corresponding to the first object. Additionally or alternatively, a sixth difference of the plurality of differences may correspond to a difference in measurements between first sensor data collected from a sensor in the real-world driving scene and second sensor data generated by a sensor model in the simulated driving scene. The first and second sensor data may be associated with the same sensing modality (e.g., camera sensors, LIDAR sensors, or RADAR sensors).

While the processes 500, 600, 700 are discussed in the context of determining a fidelity of an E2E AV simulation based on how well the E2E AV simulation replicates a real-world driving scene, in some examples, the processes 500, 600, and/or 700 can be used to determine a fidelity of an E2E AV simulation (e.g., E2E AV simulations 131 and 211) with respect to any suitable reference driving scene (e.g., another high-fidelity synthetic E2E AV simulation).

Turning now to FIG. 8, this figure illustrates an example of an AV management system 800. One of ordinary skill in the art will understand that, for the AV management system 800 and any system discussed in the present disclosure, there may be additional or fewer components in similar or alternative configurations. The illustrations and examples provided in the present disclosure are for conciseness and clarity. Other embodiments may include different numbers and/or types of elements, but one of ordinary skill the art will appreciate that such variations do not depart from the scope of the present disclosure.

In this example, the AV management system 800 includes an AV 802, a data center 850, and a client computing device 870. The AV 802, the data center 850, and the client computing device 870 may communicate with one another over one or more networks (not shown), such as a public network (e.g., the Internet, an Infrastructure as a Service (IaaS) network, a Platform as a Service (PaaS) network, a Software as a Service (SaaS) network, another Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.).

AV 802 may navigate about roadways without a human driver based on sensor signals generated by multiple sensor systems 804, 806, and 808. The sensor systems 804-708 may include different types of sensors and may be arranged about the AV 802. For instance, the sensor systems 804-808 may comprise Inertial Measurement Units (IMUs), cameras (e.g., still image cameras, video cameras, etc.), light sensors (e.g., LIDAR systems, ambient light sensors, infrared sensors, etc.), RADAR systems, a Global Navigation Satellite System (GNSS) receiver, (e.g., Global Positioning System (GPS) receivers), audio sensors (e.g., microphones, Sound Navigation and Ranging (SONAR) systems, ultrasonic sensors, etc.), engine sensors, speedometers, tachometers, odometers, altimeters, tilt sensors, impact sensors, airbag sensors, seat occupancy sensors, open/closed door sensors, tire pressure sensors, rain sensors, and so forth. For example, the sensor system 804 may be a camera system, the sensor system 806 may be a LIDAR system, and the sensor system 808 may be a RADAR system. Other embodiments may include any other number and type of sensors.

AV 802 may also include several mechanical systems that may be used to maneuver or operate AV 802. For instance, the mechanical systems may include vehicle propulsion system 830, braking system 832, steering system 834, safety system 836, and cabin system 838, among other systems. Vehicle propulsion system 830 may include an electric motor, an internal combustion engine, or both. The braking system 832 may include an engine brake, a wheel braking system (e.g., a disc braking system that utilizes brake pads), hydraulics, actuators, and/or any other suitable componentry configured to assist in decelerating AV 802. The steering system 834 may include suitable componentry configured to control the direction of movement of the AV 802 during navigation. Safety system 836 may include lights and signal indicators, a parking brake, airbags, and so forth. The cabin system 838 may include cabin temperature control systems, in-cabin entertainment systems, and so forth. In some embodiments, the AV 802 may not include human driver actuators (e.g., steering wheel, handbrake, foot brake pedal, foot accelerator pedal, turn signal lever, window wipers, etc.) for controlling the AV 802. Instead, the cabin system 838 may include one or more client interfaces (e.g., Graphical User Interfaces (GUIs), Voice User Interfaces (VUIs), etc.) for controlling certain aspects of the mechanical systems 830-838.

AV 802 may additionally include a local computing device 810 that is in communication with the sensor systems 804-808, the mechanical systems 830-838, the data center 850, and the client computing device 870, among other systems. The local computing device 810 may include one or more processors and memory, including instructions that may be executed by the one or more processors. The instructions may make up one or more software stacks or components responsible for controlling the AV 802; communicating with the data center 850, the client computing device 870, and other systems; receiving inputs from riders, passengers, and other entities within the AV's environment; logging metrics collected by the sensor systems 804-808; and so forth. In this example, the local computing device 810 includes a perception stack 812, a mapping and localization stack 814, a planning stack 816, a control stack 818, a communications stack 820, an HD geospatial database 822, and an AV operational database 824, among other stacks and systems.

Perception stack 812 may enable the AV 802 to “see” (e.g., via cameras, LIDAR sensors, infrared sensors, etc.), “hear” (e.g., via microphones, ultrasonic sensors, RADAR, etc.), and “feel” (e.g., pressure sensors, force sensors, impact sensors, etc.) its environment using information from the sensor systems 804-808, the mapping and localization stack 814, the HD geospatial database 822, other components of the AV, and other data sources (e.g., the data center 850, the client computing device 870, third-party data sources, etc.). The perception stack 812 may detect and classify objects and determine their current and predicted locations, speeds, directions, and the like. In addition, the perception stack 812 may determine the free space around the AV 802 (e.g., to maintain a safe distance from other objects, change lanes, park the AV, etc.). The perception stack 812 may also identify environmental uncertainties, such as where to look for moving objects, flag areas that may be obscured or blocked from view, and so forth.

Mapping and localization stack 814 may determine the AV's position and orientation (pose) using different methods from multiple systems (e.g., GPS, IMUs, cameras, LIDAR, RADAR, ultrasonic sensors, the HD geospatial database 822, etc.). For example, in some embodiments, the AV 802 may compare sensor data captured in real-time by the sensor systems 804-808 to data in the HD geospatial database 822 to determine its precise (e.g., accurate to the order of a few centimeters or less) position and orientation. The AV 802 may focus its search based on sensor data from one or more first sensor systems (e.g., GPS) by matching sensor data from one or more second sensor systems (e.g., LIDAR). If the mapping and localization information from one system is unavailable, the AV 802 may use mapping and localization information from a redundant system and/or from remote data sources.

The planning stack 816 may determine how to maneuver or operate the AV 802 safely and efficiently in its environment. For example, the planning stack 816 may receive the location, speed, and direction of the AV 802, geospatial data, data regarding objects sharing the road with the AV 802 (e.g., pedestrians, bicycles, vehicles, ambulances, buses, cable cars, trains, traffic lights, lanes, road markings, etc.) or certain events occurring during a trip (e.g., an Emergency Vehicle (EMV) blaring a siren, intersections, occluded areas, street closures for construction or street repairs, Double-Parked Vehicles (DPVs), etc.), traffic rules and other safety standards or practices for the road, user input, and other relevant data for directing the AV 802 from one point to another. The planning stack 816 may determine multiple sets of one or more mechanical operations that the AV 802 may perform (e.g., go straight at a specified speed or rate of acceleration, including maintaining the same speed or decelerating; turn on the left blinker, decelerate if the AV is above a threshold range for turning, and turn left; turn on the right blinker, accelerate if the AV is stopped or below the threshold range for turning, and turn right; decelerate until completely stopped and reverse; etc.), and select the best one to meet changing road conditions and events. If something unexpected happens, the planning stack 816 may select from multiple backup plans to carry out. For example, while preparing to change lanes to turn right at an intersection, another vehicle may aggressively cut into the destination lane, making the lane change unsafe. The planning stack 816 could have already determined an alternative plan for such an event, and upon its occurrence, help to direct the AV 802 to go around the block instead of blocking a current lane while waiting for an opening to change lanes.

The control stack 818 may manage the operation of the vehicle propulsion system 830, the braking system 832, the steering system 834, the safety system 836, and the cabin system 838. The control stack 818 may receive sensor signals from the sensor systems 804-808 as well as communicate with other stacks or components of the local computing device 810 or a remote system (e.g., the data center 850) to effectuate operation of the AV 802. For example, the control stack 818 may implement the final path or actions from the multiple paths or actions provided by the planning stack 816. Implementation may involve turning the routes and decisions from the planning stack 816 into commands for the actuators that control the AV's steering, throttle, brake, and drive unit.

The communication stack 820 may transmit and receive signals between the various stacks and other components of the AV 802 and between the AV 802, the data center 850, the client computing device 870, and other remote systems. The communication stack 820 may enable the local computing device 810 to exchange information remotely over a network, such as through an antenna array or interface that may provide a metropolitan WIFI® network connection, a mobile or cellular network connection (e.g., Third Generation (3G), Fourth Generation (4G), Long-Term Evolution (LTE), 5th Generation (5G), etc.), and/or other wireless network connection (e.g., License Assisted Access (LAA), Citizens Broadband Radio Service (CBRS), MULTEFIRE, etc.). The communication stack 820 may also facilitate local exchange of information, such as through a wired connection (e.g., a user's mobile computing device docked in an in-car docking station or connected via Universal Serial Bus (USB), etc.) or a local wireless connection (e.g., Wireless Local Area Network (WLAN), Bluetooth®, infrared, etc.).

The HD geospatial database 822 may store HD maps and related data of the streets upon which the AV 802 travels. In some embodiments, the HD maps and related data may comprise multiple layers, such as an areas layer, a lanes and boundaries layer, an intersections layer, a traffic controls layer, and so forth. The areas layer may include geospatial information indicating geographic areas that are drivable (e.g., roads, parking areas, shoulders, etc.) or not drivable (e.g., medians, sidewalks, buildings, etc.), drivable areas that constitute links or connections (e.g., drivable areas that form the same road) versus intersections (e.g., drivable areas where two or more roads intersect), and so on. The lanes and boundaries layer may include geospatial information of road lanes (e.g., lane or road centerline, lane boundaries, type of lane boundaries, etc.) and related attributes (e.g., direction of travel, speed limit, lane type, etc.). The lanes and boundaries layer may also include 3D attributes related to lanes (e.g., slope, elevation, curvature, etc.). The intersections layer may include geospatial information of intersections (e.g., crosswalks, stop lines, turning lane centerlines, and/or boundaries, etc.) and related attributes (e.g., permissive, protected/permissive, or protected only left-turn lanes; permissive, protected/permissive, or protected only U-turn lanes; permissive or protected only right-turn lanes; etc.). The traffic controls layer may include geospatial information of traffic signal lights, traffic signs, and other road objects and related attributes.

The AV operational database 824 may store raw AV data generated by the sensor systems 804-708 and other components of the AV 802 and/or data received by the AV 802 from remote systems (e.g., the data center 850, the client computing device 870, etc.). In some embodiments, the raw AV data may include HD LIDAR point cloud data, image or video data, RADAR data, GPS data, and other sensor data that the data center 850 may use for creating or updating AV geospatial data as discussed further below with respect to FIG. 5 and elsewhere in the present disclosure.

The data center 850 may be a private cloud (e.g., an enterprise network, a co-location provider network, etc.), a public cloud (e.g., an Infrastructure as a Service (IaaS) network, a Platform as a Service (PaaS) network, a Software as a Service (SaaS) network, or other Cloud Service Provider (CSP) network), a hybrid cloud, a multi-cloud, and so forth. The data center 850 may include one or more computing devices remote to the local computing device 810 for managing a fleet of AVs and AV-related services. For example, in addition to managing the AV 802, the data center 850 may also support a ridesharing service, a delivery service, a remote/roadside assistance service, street services (e.g., street mapping, street patrol, street cleaning, street metering, parking reservation, etc.), and the like.

The data center 850 may send and receive various signals to and from the AV 802 and the client computing device 870. These signals may include sensor data captured by the sensor systems 804-808, roadside assistance requests, software updates, ridesharing pick-up and drop-off instructions, and so forth. In this example, the data center 850 includes one or more of a data management platform 852, an Artificial Intelligence/Machine Learning (AI/ML) platform 854, a simulation platform 856, a remote assistance platform 858, a ridesharing platform 860, and a map management platform 862, among other systems.

Data management platform 852 may be a “big data” system capable of receiving and transmitting data at high speeds (e.g., near real-time or real-time), processing a large variety of data, and storing large volumes of data (e.g., terabytes, petabytes, or more of data). The varieties of data may include data having different structures (e.g., structured, semi-structured, unstructured, etc.), data of different types (e.g., sensor data, mechanical system data, ridesharing service data, map data, audio data, video data, etc.), data associated with different types of data stores (e.g., relational databases, key-value stores, document databases, graph databases, column-family databases, data analytic stores, search engine databases, time series databases, object stores, file systems, etc.), data originating from different sources (e.g., AVs, enterprise systems, social networks, etc.), data having different rates of change (e.g., batch, streaming, etc.), or data having other heterogeneous characteristics. The various platforms and systems of the data center 850 may access data stored by the data management platform 852 to provide their respective services.

The AI/ML platform 854 may provide the infrastructure for training and evaluating machine learning algorithms for operating the AV 802, the simulation platform 856, the remote assistance platform 858, the ridesharing platform 860, the map management platform 862, and other platforms and systems. Using the AI/ML platform 854, data scientists may prepare data sets from the data management platform 852; select, design, and train machine learning models; evaluate, refine, and deploy the models; maintain, monitor, and retrain the models; and so on.

The simulation platform 856 may enable testing and validation of the algorithms, machine learning models, neural networks, and other development efforts for the AV 802, the remote assistance platform 858, the ridesharing platform 860, the map management platform 862, and other platforms and systems. The simulation platform 856 may replicate a variety of driving environments and/or reproduce real-world scenarios from data captured by the AV 802, including rendering geospatial information and road infrastructure (e.g., streets, lanes, crosswalks, traffic lights, stop signs, etc.) obtained from the map management platform 862; modeling the behavior of other vehicles, bicycles, pedestrians, and other dynamic elements; simulating inclement weather conditions, different traffic scenarios; and so on. In some embodiments, the simulation platform 856 may include a simulation fidelity measurement block 857 (e.g., similar to the simulation fidelity calculation block 160, the E2E simulation fidelity calculation block 230, the simulation component fidelity calculation block 260, and the simulation fidelity calculation block 302) that calculates a fidelity metric or value for an E2E AV simulation and/or one or more component simulations as discussed herein.

The remote assistance platform 858 may generate and transmit instructions regarding the operation of the AV 802. For example, in response to an output of the AI/ML platform 854 or other system of the data center 850, the remote assistance platform 858 may prepare instructions for one or more stacks or other components of the AV 802.

The ridesharing platform 860 may interact with a customer of a ridesharing service via a ridesharing application 872 executing on the client computing device 870. The client computing device 870 may be any type of computing system, including a server, desktop computer, laptop, tablet, smartphone, smart wearable device (e.g., smart watch; smart eyeglasses or other Head-Mounted Display (HMD); smart ear pods or other smart in-ear, on-ear, or over-ear device; etc.), gaming system, or other general-purpose computing device for accessing the ridesharing application 872. The client computing device 870 may be a customer's mobile computing device or a computing device integrated with the AV 802 (e.g., the local computing device 810). The ridesharing platform 860 may receive requests to be picked up or dropped off from the ridesharing application 872 and dispatch the AV 802 for the trip.

Map management platform 862 may provide a set of tools for the manipulation and management of geographic and spatial (geospatial) and related attribute data. The data management platform 852 may receive LIDAR point cloud data, image data (e.g., still image, video, etc.), RADAR data, GPS data, and other sensor data (e.g., raw data) from one or more AVs 802, Unmanned Aerial Vehicles (UAVs), satellites, third-party mapping services, and other sources of geospatially referenced data. The raw data may be processed, and map management platform 862 may render base representations (e.g., tiles (2D), bounding volumes (3D), etc.) of the AV geospatial data to enable users to view, query, label, edit, and otherwise interact with the data. Map management platform 862 may manage workflows and tasks for operating on the AV geospatial data. Map management platform 862 may control access to the AV geospatial data, including granting or limiting access to the AV geospatial data based on user-based, role-based, group-based, task-based, and other attribute-based access control mechanisms. Map management platform 862 may provide version control for the AV geospatial data, such as to track specific changes that (human or machine) map editors have made to the data and to revert changes when necessary. Map management platform 862 may administer release management of the AV geospatial data, including distributing suitable iterations of the data to different users, computing devices, AVs, and other consumers of HD maps. Map management platform 862 may provide analytics regarding the AV geospatial data and related data, such as to generate insights relating to the throughput and quality of mapping tasks.

In some embodiments, the map viewing services of map management platform 862 may be modularized and deployed as part of one or more of the platforms and systems of the data center 850. For example, the AI/ML platform 854 may incorporate the map viewing services for visualizing the effectiveness of various object detection or object classification models, the simulation platform 856 may incorporate the map viewing services for recreating and visualizing certain driving scenarios, the remote assistance platform 858 may incorporate the map viewing services for replaying traffic incidents to facilitate and coordinate aid, the ridesharing platform 860 may incorporate the map viewing services into the client application 872 to enable passengers to view the AV 802 in transit enroute to a pick-up or drop-off location, and so on.

FIG. 9 illustrates an example processor-based system with which some aspects of the subject technology may be implemented. For example, processor-based system 900 may be any computing device making up, or any component thereof in which the components of the system are in communication with each other using connection 905. Connection 905 may be a physical connection via a bus, or a direct connection into processor 910, such as in a chipset architecture. Connection 905 may also be a virtual connection, networked connection, or logical connection.

In some embodiments, computing system 900 is a distributed system in which the functions described in this disclosure may be distributed within a datacenter, multiple data centers, a peer network, etc. In some embodiments, one or more of the described system components represents many such components each performing some or all of the function for which the component is described. In some embodiments, the components may be physical or virtual devices.

Example system 900 includes at least one processing unit (Central Processing Unit (CPU) or processor) 910 and connection 905 that couples various system components including system memory 915, such as Read-Only Memory (ROM) 920 and Random-Access Memory (RAM) 925 to processor 910. Computing system 900 may include a cache of high-speed memory 912 connected directly with, in close proximity to, or integrated as part of processor 910.

Processor 910 may include any general-purpose processor and a hardware service or software service, such as a simulation integrity validation model 932 and a simulation fidelity measurement block 936 stored in storage device 930, configured to control processor 910 as well as a special-purpose processor where software instructions are incorporated into the actual processor design. The simulation integrity validation model 932 may be similar to the simulation integrity validation model 410 and may determine an integrity of an E2E AV simulation based one component errors as discussed above with reference to FIG. 4. The simulation fidelity measurement block 936 may calculate a fidelity metric or value for an E2E AV simulation and/or one or more component simulations as discussed herein. Processor 910 may essentially be a completely self-contained computing system, containing multiple cores or processors, a bus, memory controller, cache, etc. A multi-core processor may be symmetric or asymmetric.

To enable user interaction, computing system 900 includes an input device 945, which may represent any number of input mechanisms, such as a microphone for speech, a touch-sensitive screen for gesture or graphical input, keyboard, mouse, motion input, speech, etc. Computing system 900 may also include output device 935, which may be one or more of a number of output mechanisms known to those of skill in the art. In some instances, multimodal systems may enable a user to provide multiple types of input/output to communicate with computing system 900. Computing system 900 may include communications interface 940, which may generally govern and manage the user input and system output. The communication interface may perform or facilitate receipt and/or transmission wired or wireless communications via wired and/or wireless transceivers, including those making use of an audio jack/plug, a microphone jack/plug, a Universal Serial Bus (USB) port/plug, an Apple® Lightning® port/plug, an Ethernet port/plug, a fiber optic port/plug, a proprietary wired port/plug, a BLUETOOTH® wireless signal transfer, a BLUETOOTH® low energy (BLE) wireless signal transfer, an IBEACON® wireless signal transfer, a Radio-Frequency Identification (RFID) wireless signal transfer, Near-Field Communications (NFC) wireless signal transfer, Dedicated Short Range Communication (DSRC) wireless signal transfer, 902.11 Wi-Fi® wireless signal transfer, Wireless Local Area Network (WLAN) signal transfer, Visible Light Communication (VLC) signal transfer, Worldwide Interoperability for Microwave Access (WiMAX), Infrared (IR) communication wireless signal transfer, Public Switched Telephone Network (PSTN) signal transfer, Integrated Services Digital Network (ISDN) signal transfer, 3G/4G/5G/LTE cellular data network wireless signal transfer, ad-hoc network signal transfer, radio wave signal transfer, microwave signal transfer, infrared signal transfer, visible light signal transfer signal transfer, ultraviolet light signal transfer, wireless signal transfer along the electromagnetic spectrum, or some combination thereof.

Communication interface 940 may also include one or more Global Navigation Satellite System (GNSS) receivers or transceivers that are used to determine a location of the computing system 900 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 930 may be a non-volatile and/or non-transitory and/or computer-readable memory device and may be a hard disk or other types of computer-readable media which may store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a Compact Disc (CD) Read Only Memory (CD-ROM) optical disc, a rewritable CD optical disc, a Digital Video Disk (DVD) optical disc, a Blu-ray Disc (BD) optical disc, a holographic optical disk, another optical medium, a Secure Digital (SD) card, a micro SD (microSD) card, a Memory Stick® card, a smartcard chip, a EMV chip, a Subscriber Identity Module (SIM) card, a mini/micro/nano/pico SIM card, another Integrated Circuit (IC) chip/card, Random-Access Memory (RAM), Atatic RAM (SRAM), Dynamic RAM (DRAM), Read-Only Memory (ROM), Programmable ROM (PROM), Erasable PROM (EPROM), Electrically Erasable PROM (EEPROM), flash EPROM (FLASHEPROM), cache memory (L1/L2/L3/L4/L5/L #), Resistive RAM (RRAM/ReRAM), Phase Change Memory (PCM), Spin Transfer Torque RAM (STT-RAM), another memory chip or cartridge, and/or a combination thereof.

Storage device 930 may include software services, servers, services, etc., that when the code that defines such software is executed by the processor 910, it causes the system 900 to perform a function. In some embodiments, a hardware service that performs a particular function may include the software component stored in a computer-readable medium in connection with the necessary hardware components, such as processor 910, connection 905, output device 935, etc., to carry out the function.

Embodiments within the scope of the present disclosure may also include tangible and/or non-transitory computer-readable storage media or devices for carrying or having computer-executable instructions or data structures stored thereon. Such tangible computer-readable storage devices may be any available device that may be accessed by a general-purpose or special purpose computer, including the functional design of any special purpose processor as described above. By way of example, and not limitation, such tangible computer-readable devices may include RAM, ROM, EEPROM, CD-ROM or other optical disk storage, magnetic disk storage or other magnetic storage devices, or any other device which may be used to carry or store desired program code in the form of computer-executable instructions, data structures, or processor chip design. When information or instructions are provided via a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general-purpose computer, special purpose computer, or special purpose processing device to perform a certain function or group of functions. Computer-executable instructions also include program modules that are executed by computers in stand-alone or network environments. Generally, program modules include routines, programs, components, data structures, objects, and the functions inherent in the design of special-purpose processors, etc. that perform tasks or implement abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Other embodiments of the disclosure may be practiced in network computing environments with many types of computer system configurations, including personal computers, hand-held devices, multi-processor systems, microprocessor-based or programmable consumer electronics, network Personal Computers (PCs), minicomputers, mainframe computers, and the like. Embodiments may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

### Selected Examples

Example 1 includes a computer-implemented system, including one or more processing units; and one or more non-transitory computer-readable media storing instructions, when executed by the one or more processing units, cause the one or more processing units to perform operations including receiving first data collected from a reference driving scene, the first data associated with the reference driving scene and a driving behavior of a first vehicle in the reference driving scene; receiving second data collected from a driving simulation including a simulated driving scene and a second vehicle, wherein the simulated driving scene is a simulation of the reference driving scene and the second data associated with the simulated driving scene and a driving behavior of the second vehicle in the simulated driving scene; and determining a fidelity of the simulation based on a comparison between the first data and the second data.

In Example 2, the computer-implemented system of example 1 can optionally include where the reference driving scene is a real-world driving scene.

In Example 3, the computer-implemented system of any of examples 1-2 can optionally include where the reference driving scene is another simulated driving scene replicating a real-world driving scene.

In Example 4, the computer-implemented system of any of examples 1-3 can optionally include where the determining the fidelity of the driving simulation includes comparing the driving behavior of the first vehicle in the reference driving scene at a first time instant to the driving behavior of the second vehicle in the simulated driving scene at a second time instant corresponding to the first time instant.

In Example 5, the computer-implemented system of any of examples 1-4 can optionally include where the first data includes an indication of a pose of the first vehicle with respect to the reference driving scene; the second data includes an indication of a pose of the second vehicle with respect to the simulated driving scene; and the determining the fidelity of the driving simulation includes comparing the pose of the first vehicle with respect to the reference driving scene to the pose of the second vehicle with respect to the simulated driving scene.

In Example 6, the computer-implemented system of any of examples 1-5 can optionally include where the first data includes an indication of a vehicle dynamic of the first vehicle; the second data includes an indication of a vehicle dynamic of the second vehicle; and the determining the fidelity of the driving simulation includes comparing the vehicle dynamic of the first vehicle to the vehicle dynamic of the second vehicle.

In Example 7, the computer-implemented system of any of examples 1-6 can optionally include where the first data includes an indication of a placement of a first object in the reference driving scene; the second data includes an indication of a placement of a second object in the simulated driving scene; and the determining the fidelity of the driving simulation includes comparing the placement of the first object in the reference driving scene to the placement of the second object in the simulated driving scene.

In Example 8, the computer-implemented system of any of examples 1-7 can optionally include where the first data includes an indication of an attribute of a first road in the reference driving scene; the second data includes an indication of an attribute of a second road in the simulated driving scene; and the determining the fidelity of the driving simulation includes comparing the attribute of the first road in the reference driving scene to the attribute of the second road in the simulated driving scene.

In Example 9, the computer-implemented system of any of examples 1-8 can optionally include where the first data includes a classification of a first object in the reference driving scene determined by the first vehicle; the second data includes a classification of a second object in the simulated driving scene determined by the second vehicle; and the determining the fidelity of the driving simulation includes comparing the classification of the first object to the classification of the second object.

In Example 10, the computer-implemented system of any of examples 1-9 can optionally include where the first data includes first sensor data collected from the reference driving scene; the second data includes second sensor data collected from the simulated driving scene; and the determining the fidelity of the driving simulation includes comparing the first sensor data to the second sensor data.

In Example 11, the computer-implemented system of any of examples 1-10 can optionally include where the first sensor data is collected from a sensor of the first vehicle; the second sensor data is collected from a simulated sensor in the simulated driving scene; and the sensor of the first vehicle and the simulated sensor are of the same sensor modality.

In Example 12, the computer-implemented system of any of examples 1-11 can optionally include where the first sensor data and the second sensor data are light detection and ranging (LIDAR) data; and the comparing the first sensor data to the second sensor data includes determining at least one of a difference in a total number of LIDAR points, intensities, or spatial distributions between the first sensor data and the second sensor data.

In Example 13, the computer-implemented system of any of examples 1-11 can optionally include where the first sensor data and the second sensor data are camera images; and the comparing the first sensor data to the second sensor data includes determining at least one of a difference in colors, intensities, or dynamic ranges between the first sensor data and the second sensor data.

In Example 14, the computer-implemented system of any of examples 1-11 can optionally include where the first sensor data and the second sensor data are radio detection and ranging (RADAR) data; and the comparing the first sensor data to the second sensor data includes determining a difference in a total number of RADAR data points between the first sensor data and the second sensor data.

Example 15 includes a computer-implemented system, including one or more processing units; and one or more non-transitory computer-readable media storing instructions, when executed by the one or more processing units, cause the one or more processing units to perform operations including executing a simulation that simulates a simulated vehicle driving in a simulated driving scene; collecting, from the simulation, first data associated with the simulated driving scene and a driving behavior of the simulated vehicle in the simulated driving scene; determining a plurality of differences between measurements of the first data and second data, the second data associated with a real-world driving scene and a driving behavior of a real-world vehicle in the real-world driving scene; and processing the plurality of differences using a simulation integrity validation model to generate a simulation integrity score.

In Example 16, the computer-implemented system of example 15, where an individual difference of the plurality of differences corresponds to a difference between a component of a plurality of components in the real-world driving scene and a respective one of a plurality of simulated components used by the simulation.

In Example 17, the computer-implemented system of any of examples 15-16 can optionally include where the simulation integrity validation model is a statistical model.

In Example 18, the computer-implemented system of any of examples 15-16 can optionally include where the simulation integrity validation model comprises at least one of a generalized linear model (GLM) or a machine learning (ML) model.

In Example 19, the computer-implemented system of any of examples 15-16 can optionally include where the simulation integrity score includes an indication of a pass or a failure.

In Example 20, the computer-implemented system of any of examples 15-19 can optionally include where the simulation integrity score is one or zero.

In Example 21, the computer-implemented system of any of examples 15-20 can optionally include where a first difference of the plurality of differences corresponds to a difference between a pose of the real-world vehicle in the real-world driving scene and a pose of the simulated vehicle in the simulated driving scene.

In Example 22, the computer-implemented system of any of examples 15-21 can optionally include where a first difference of the plurality of differences corresponds to a difference between a vehicle dynamic of the real-world vehicle in the real-world driving scene and a vehicle dynamic of the simulated vehicle in the simulated driving scene.

In Example 23, the computer-implemented system of any of examples 15-22 can optionally include where a first difference of the plurality of differences corresponds to a difference between a road attribute in the real-world driving scene and a road attribute in the simulated driving scene.

In Example 24, the computer-implemented system of any of examples 15-23 can optionally include where a first difference of the plurality of differences corresponds to a difference between a placement of a first asset in the real-world driving scene and a placement of a second asset in the simulated driving scene, the second asset corresponding to the first asset.

In Example 25, the computer-implemented system of any of examples 15-24 can optionally include where a first difference of the plurality of differences corresponds to a difference between a classification of a first object in the real-world driving scene and a classification of a second object in the simulated driving scene, the second object corresponding to the first object.

In Example 26, the computer-implemented system of any of examples 15-25 can optionally include where a first difference of the plurality of differences corresponds to a difference between first sensor data collected from a sensor in the real-world driving scene and second sensor data generated by a sensor model in the simulated driving scene.

Example 27 includes a method including receiving first data collected from a real-world driving scene, the first data associated with the real-world driving scene and a performance of a real-world vehicle in the real-world driving scene; and adjusting, for a current iteration, a parameter associated with an end-to-end (E2E) vehicle simulation that simulates operations of a simulated vehicle driving in a simulated driving scene, where the adjustment is based on a fidelity value of the E2E vehicle simulation in a previous iteration, and the fidelity value is based on a comparison between second data collected from the E2E simulation in the previous iteration and the first data.

In Example 28, the method of example 27 can optionally include where adjusting the parameter associated with the E2E vehicle simulation includes executing the E2E vehicle simulation; collecting, from the E2E vehicle simulation, the second data associated with the simulated driving scene and a performance of the simulated vehicle in the simulated driving scene; and calculating the fidelity value for the E2E vehicle simulation based on a comparison between the first data and the second data.

In Example 29, the method of any of examples 27-28 can optionally include where the parameter adjusted based on the fidelity value of the E2E vehicle simulation in a previous iteration is for a component model modeling a component in the real-world driving scene.

In Example 30, the method of any of examples 27-29 can optionally include where the component is associated with at least one of a sensor in the real-world driving scene, an object in the real-world driving scene, a pose of the real-world vehicle, a vehicle dynamic of the real-world vehicle, or a road attribute.

In Example 31, the method of any of examples 27-30 can optionally include where the adjusting the parameter associated with the E2E vehicle simulation includes identifying a mismatch between the component in the real-world driving scene and the component model in the simulated driving scene.

In Example 32, the method of any of examples 27-31 can optionally include where the adjusting the parameter associated with the E2E vehicle simulation includes executing, based on a component test definition, a test for the component model; collecting third data from the executing the test; receiving fourth data collected from the component in the real-world driving scene, the fourth data based on the component test definition; and calculating a fidelity value for the component model based on a comparison of the third data to the fourth data.

In Example 33, the method of any of examples 27-31 can optionally include where the adjusting the parameter associated with the E2E vehicle simulation include is based on the fidelity value in the previous iteration failing to satisfy a threshold.

Example 34 includes an apparatus comprising means for performing operation of any one of the preceding examples.

The various embodiments described above are provided by way of illustration only and should not be construed to limit the scope of the disclosure. For example, the principles herein apply equally to optimization as well as general improvements. Various modifications and changes may be made to the principles described herein without following the example embodiments and applications illustrated and described herein, and without departing from the spirit and scope of the disclosure. Claim language reciting “at least one of” a set indicates that one member of the set or multiple members of the set satisfy the claim.

1. A computer-implemented system, comprising:
one or more processing units; and
one or more non-transitory computer-readable media storing instructions, when executed by the one or more processing units, cause the one or more processing units to perform operations comprising:
receiving first data collected from a reference driving scene, the first data associated with the reference driving scene and a driving behavior of a first vehicle in the reference driving scene;
receiving second data collected from a driving simulation that generates a simulated driving scene and operations of a second vehicle located in the simulated driving scene, wherein the simulated driving scene is a simulation of the reference driving scene, and wherein the second data is associated with the simulated driving scene and a driving behavior of the second vehicle in the simulated driving scene; and
determining a fidelity of the driving simulation based on a comparison between the first data and the second data.

2. The computer-implemented system of claim 1, wherein the reference driving scene is a real-world driving scene.

3. The computer-implemented system of claim 1, wherein the determining the fidelity of the driving simulation comprises:
comparing the driving behavior of the first vehicle in the reference driving scene at a first time instant to the driving behavior of the second vehicle in the simulated driving scene at a second time instant, the second time instant based on a correlation between a first timestamp in the first data and a second timestamp in the second data.

4. The computer-implemented system of claim 1, wherein:
the first data includes an indication of a pose of the first vehicle with respect to the reference driving scene;
the second data includes an indication of a pose of the second vehicle with respect to the simulated driving scene; and
the determining the fidelity of the driving simulation comprises:
comparing the pose of the first vehicle with respect to the reference driving scene to the pose of the second vehicle with respect to the simulated driving scene.

5. The computer-implemented system of claim 1, wherein:
the first data includes an indication of a vehicle dynamic of the first vehicle;
the second data includes an indication of a vehicle dynamic of the second vehicle; and
the determining the fidelity of the driving simulation comprises:
comparing the vehicle dynamic of the first vehicle to the vehicle dynamic of the second vehicle.

6. The computer-implemented system of claim 1, wherein:
the first data includes an indication of a placement of a first object in the reference driving scene;
the second data includes an indication of a placement of a second object in the simulated driving scene; and
the determining the fidelity of the driving simulation comprises:
comparing the placement of the first object in the reference driving scene to the placement of the second object in the simulated driving scene.

7. The computer-implemented system of claim 1, wherein:
the first data includes an indication of an attribute of a first road in the reference driving scene;
the second data includes an indication of an attribute of a second road in the simulated driving scene; and
the determining the fidelity of the driving simulation comprises:
comparing the attribute of the first road in the reference driving scene to the attribute of the second road in the simulated driving scene.

8. The computer-implemented system of claim 1, wherein:
the first data includes a classification of a first object in the reference driving scene determined by the first vehicle;
the second data includes a classification of a second object in the simulated driving scene determined by the second vehicle; and
the determining the fidelity of the driving simulation comprises:
comparing the classification of the first object to the classification of the second object.

9. The computer-implemented system of claim 1, wherein:
the first data includes first sensor data collected from the reference driving scene;
the second data includes second sensor data collected from the simulated driving scene; and
the determining the fidelity of the driving simulation comprises:
comparing the first sensor data to the second sensor data.

10. The computer-implemented system of claim 9, wherein:
the first sensor data is collected from a sensor of the first vehicle;
the second sensor data is collected from a simulated sensor in the simulated driving scene; and
the sensor of the first vehicle and the simulated sensor are of the same sensor modality.

11. A computer-implemented system, comprising:
one or more processing units; and
one or more non-transitory computer-readable media storing instructions, when executed by the one or more processing units, cause the one or more processing units to perform operations comprising:
executing a simulation that simulates operations of a simulated vehicle driving in a simulated driving scene;
collecting, from the simulation, first data associated with the simulated driving scene and a driving behavior of the simulated vehicle in the simulated driving scene;
determining a plurality of differences between measurements of the first data and second data, the second data associated with a real-world driving scene and a driving behavior of a real-world vehicle in the real-world driving scene; and
processing the plurality of differences using a simulation integrity validation model to generate a simulation integrity score.

12. The computer-implemented system of claim 11, wherein an individual difference of the plurality of differences corresponds to a difference between a component of a plurality of components in the real-world driving scene and a respective one of a plurality of simulated components used by the simulation.

13. The computer-implemented system of claim 11, wherein the simulation integrity validation model is a statistical model.

14. The computer-implemented system of claim 11, wherein the simulation integrity validation model is a generalized linear model (GLM).

15. The computer-implemented system of claim 11, wherein the simulation integrity score includes an indication of a pass or a failure.

16. A method comprising:
receiving, by a computer-implemented system, first data collected from a reference driving scene, the first data associated with the reference driving scene and a driving behavior of a first vehicle in the reference driving scene;
receiving, by the computer-implemented system, second data collected from an end-to-end (E2E) vehicle simulation of a simulated driving scene and operations of a second vehicle in the simulated driving scene, wherein the simulated driving scene is a simulation of the reference driving scene, and wherein the second data is associated with the simulated driving scene and a driving behavior of the second vehicle in the simulated driving scene; and
determining, by the computer-implemented system, a fidelity of the E2E simulation based on a comparison between the first data and the second data.

17. The method of claim 16, wherein the determining the fidelity of the E2E simulation comprises:
comparing the driving behavior of the first vehicle in the reference driving scene at a first time instant to the driving behavior of the second vehicle in the simulated driving scene at a second time instant corresponding to the first time instant.

18. The method of claim 16, wherein:
the first data includes an indication of a pose of the first vehicle with respect to the reference driving scene;
the second data includes an indication of a pose of the second vehicle with respect to the simulated driving scene; and
the determining the fidelity of the E2E simulation comprises:
comparing the pose of the first vehicle with respect to the reference driving scene to the pose of the second vehicle with respect to the simulated driving scene.

19. The method of claim 16, wherein:
the first data includes an indication of a placement of a first object in the reference driving scene;
the second data includes an indication of a placement of a second object in the simulated driving scene; and
the determining the fidelity of the E2E simulation comprises:
comparing the placement of the first object in the reference driving scene to the placement of the second object in the simulated driving scene.

20. The method of claim 16, wherein:
the first data includes first sensor data collected from the reference driving scene;
the second data includes second sensor data collected from the simulated driving scene; and
the determining the fidelity of the E2E simulation comprises:
comparing the first sensor data to the second sensor data.
